(19) United States
(12) Patent Application Publication
(10) Pub. No.: US 2020/0158759 A1
(43) Pub. Date: May 21, 2020

(54) VOLTAGE SENSING SYSTEMS AND METHODS FOR A HIGH-POWER LINE

(71) Applicant: Awesense Wireless, Inc., Vancouver (CA)

(72) Inventors: Thomas Edward Johnson, Lake Country (CA); Jake Stanley Bobowski, Lake Country (CA); Richard Slamka, West Kelowna (CA); Mischa Steiner-Jovic, Vancouver (CA)

(21) Appl. No.: 16/554,413

(22) Filed: Aug. 28, 2019

Related U.S. Application Data
(63) Continuation-in-part of application No. 14/888,417, filed on Oct. 30, 2015, now abandoned.
(60) Provisional application No. 61/818,851, filed on May 2, 2013.

(51) Int. Cl. G01R 15/16; G01R 27/16

(52) U.S. Cl. CPC G01R 15/16; G01R 27/16

(57) ABSTRACT

A method is provided of ascertaining an unknown line (conductor) voltage at point X on a power line within an electrical grid comprises collecting raw voltage at or about Point X1 using a sensor; gathering additional data from data collection sources upstream (comprising, for example a substation) and/or downstream (comprising, for example, one or more smart meters) to Point X1 (constraining data); using raw voltage, and environment and line data (comprising at least one of GPS location of sensor, GIS data of the electrical grid, phase, type of conductor, total load on conductor), to calculate voltage range at Point X1; and using constraining data sequentially to bind (narrow and tighten) the voltage range from a determined range of possibilities to a likely absolute voltage measurement.

### CROSS-REFERENCE TO RELATED APPLICATIONS

Parts of this application relate to U.S. application Ser. No. 14/888,417 (titled “VOLTAGE SENSING UNIT FOR SENSING VOLTAGE OF HIGH-POWER LINES USING A SINGLE-CONTACT POINT AND METHOD OF USE THEREOF” and filed 30 Oct. 2015 and to PCT App. No. PCT/CA2014/000410 (titled “VOLTAGE SENSING UNIT FOR SENSING VOLTAGE OF HIGH-POWER LINES USING A SINGLE-CONTACT POINT AND METHOD OF USE THEREOF” and filed 2 May 2014, which are incorporated by reference in their entirety.

### TECHNOLOGICAL FIELD

This disclosure relates primarily to power monitoring, such as within a power grid.

### BACKGROUND

In the generation, transmission, and distribution of electric power it is important to monitor line voltage, line current, and the phase between voltage and current (power factor). Most monitoring in the electric distribution grid is done at generation nodes and at large loads, while independent monitoring on transmission or distribution lines has been limited. However, the electric grid is evolving into a highly sophisticated and complex network as smaller generation nodes are added to the grid. The term ‘smart grid’ is now used to capture the sophisticated monitoring and control that is being deployed to improve the efficiency and stability of the grid.

Electrical utilities need to monitor their power lines to determine when lines are down or in need of repair, and when power transmission to specific areas needs to be re-routed. Transmission lines route high-voltage electrical power from power plants to main regional stations and local substations. Distribution lines route high-voltage electrical power from substations to end users. In many areas, such lines are above ground exposed to the natural elements. Thus, high winds, falling trees or other forces occurring during storms or natural disasters may de-energize or “knock out” a line.

Some electrical utility companies employ Supervisory Control—and Data Acquisition (SCADA) systems with automatic sectionalizing procedures to sense the activities of their power lines and react automatically to line failures. Typically, substations have incoming and outgoing high-voltage transmission lines which feed transformers that step down the voltage (i.e., 12 kV) for distribution to end user residences and businesses. Previously, when a power line is knocked down, a coupled voltage transformer (CVT) typically senses the loss of voltage. The CVT has a primary winding connected directly to the 115 kV line and a secondary winding driving a relay to a normally open position. When the line is knocked down, the signal across the primary winding is discontinued causing the signal on the secondary winding to discontinue. The loss of signal on the secondary winding closes the relay, starting a motor that opens switches on all de-energized 115 kV lines at the substation.

The electrical utility monitors the CVT signals via remote communication within the SCADA systems to determine which lines in a region are active. A failed power line is bypassed, when possible, and power re-routed through other lines. The CVT devices are expensive devices directly connected to power lines. The power lines need to be shut down, when possible, to install and replace such devices.

As monitoring features are enhanced in the electric grid, demand is increasing for field deployable sensors with wireless backhauls. A remote sensor can now be placed on any transmission or distribution wire to collect real time load data which is transmitted wirelessly back to a central monitoring station. These sensors can measure the current, voltage and power factor of individual high voltage lines which a few years ago was not possible. It is important that sensors which clip to wires are easy to install, safe, reliable, and accurate. Accurate measurement of current is relatively common and easily made using a current loop which couples to the magnetic field around the wire. Therefore current can easily be measured on a single conductor without contacting the conductor. On the other hand, voltage, also called potential, is much more difficult to measure on a single conductor because potential has to be reference to a second conductor. Standard voltage measurements require two points of contact across two conductors making this kind of measurement dangerous at high voltages.

One non-intrusive way of detecting the presence of electrical signals is to detect the electric field (E-field) surrounding the lines carrying the signal. There are E-field detectors known for detecting low voltage (i.e. 440 volts or less) activity. One such low voltage sensor device is manufactured by Radio Shack under the brand name Micronta™. This and other low voltage sensors over-saturate in the presence of high voltage signals (e.g. exceeding 2 kilovolts). These low-voltage sensors also have a poor response to voltage transients when over-saturated and have limited use. There is also the issue of accuracy: low cost sensors detect whether there is a voltage or not and provide an estimate of the voltage only. Accuracy takes a back seat to cost (for example, a simple sensor used to locate a hidden wire in a wall). Accordingly, there is a need for a non-contact or single contact apparatus/sensor which can measure high-voltage signals, is accurate and can be used by a utility provider. This need has not been previously met.

### BRIEF DESCRIPTION OF THE DRAWINGS

The following figures set forth embodiments in which like reference numerals denote like parts. Embodiments are illustrated by way of example and not by way of limitation in all of the accompanying figures.

FIG. 1 is a schematic of a circuit model for voltage measurement of a high-power line using a single-contact point sensor according to one or more embodiments of this invention;

FIG. 2 is a schematic of a simplified circuit model for voltage measurement of a high-power line using a single-contact point according to one or more embodiments of this invention;

FIG. 3 is schematic of a single-contact point voltage sensor comprising a switched capacitor bank and a switched resistor bank;

FIG. 4 is a graph representing experimental measurements using a calibrated sensor wherein the x-axis is the line voltage V.sub.L and y-axis is the measured voltage Vm;

FIG. 5 is a further schematic of a circuit model for voltage measurement of a high-power line using a single-contact point sensor according to one or more embodiments of this invention;

FIG. 6 is further schematic of a circuit model for voltage measurement of a high-power line using a single contact-point sensor according to one or more embodiments of this invention.

FIG. 7 is a further schematic of a circuit model with an additional capacitive voltage divider which allows the voltage sensing unit to be used in very high-voltage applications without compromising the sensitivity of the sensor;

FIG. 8 is a graph showing the linearity test of sensing voltages;

FIG. 9 is a graph showing estimated capacitance C₀ as a function of the applied line voltage;

FIG. 10 is a graph showing estimated capacitance Cg as a function of the applied line voltage;

FIG. 11 is a graph showing the estimated line voltage measured by the single-contact voltage sensor in a blind context compared to the actual applied line voltage. This is measured by the single-contact voltage sensor in a blind test compared to the actual applied line voltage. The different colour points correspond to different initial parameter values used in the non-linear fit routine. In this example, the estimated line voltage is always within 10% of the actual line voltage;

FIG. 12 is a graph showing the linear relationship between Vm and V.sub.L when the voltage sensing unit is configured for high-voltage measurements using an additional secondary capacitive divider;

FIG. 13 is an electrical grid schematic; and

FIG. 14 is a legend of reference numerals used in one or more other figures.

### DESCRIPTION

One or more embodiments described herein may (optionally) provide computer implemented methods of computing voltage at a power line within an electrical grid: (a) wherein there is no substation, no downstream (end of line feeder) measuring means (such as, for example, one or more smart meters)—and wherein computing of voltage is achieved within a fully computational voltage sensing unit, as a single contact on the power line; OR (b) wherein there is a substation with voltage measuring capacity but no downstream (end of feeder) voltage measuring means (e.g. one or more smart meters)—and wherein computing of voltage is achieved by i) collecting raw voltage data in a voltage sensing unit on the power line at Point X1 (such as, for example, a simple voltage gathering sensor, and which need not necessarily be a fully computational voltage sensing unit); ii) transmitting raw voltage data to a server on a computing system remote from the sensor (such as for example, in a Cloud), the computing system comprising a microprocessor; and iii) gathering additional data from substation to Point X1 (constraining data); iv) using raw voltage, and environment and line data (comprising at least one of GPS location of sensor, GIS data of the electrical grid, phase, type of conductor, total load on conductor), to calculate voltage range at Point X1; and v) using constraining data sequentially to bind (narrow and tighten) the voltage range from a determined range of possibilities to a likely true absolute voltage measurement at Point X1 OR (c) wherein there is a substation with voltage measuring capacity and there is at least one downstream (end of feeder) voltage measuring means (such as for example, a smart meter)—and wherein computing of voltage at Point X1 is achieved by i) collecting raw voltage data in a voltage sensing unit on the power line (such as, for example, a simple voltage gathering sensor, and which need not necessarily be a fully computational voltage sensing unit); ii) transmitting raw voltage data to a server on a computing system remote from the sensor (such as for example, in a Cloud), the computing system comprising a microprocessor; and iii) gathering additional data from substation and at least one downstream source to Point X1 (constraining data); iv) using raw voltage, and environment and line data (comprising at least one of GPS location of sensor, GIS data of the electrical grid, phase, type of conductor, total load on conductor), to calculate voltage range at Point X1; and v) using constraining data sequentially to bind (narrow and tighten) the voltage range from a determined range of possibilities to a likely absolute voltage measurement . . . .

There are described herein a plurality of computer enabled methods of computing voltage at a point on a power line, the steps of which may be conducted: a) on and within the actual power line voltage sensor, the sensor being a fully computational voltage line sensor (sensing unit); which acquires voltage data and which comprises a shielded enclosure hosting a bank of capacitors comprising at least two capacitors mounted in parallel, each of the at least two capacitors being controlled by a corresponding switch, the bank of capacitors having a first connecting contact and a second connecting contact; operatively connecting one of the two connecting contact of the voltage sensing unit to the line; for each given capacitor of the at least two capacitors; selecting the given capacitor using a corresponding switch; measuring a corresponding voltage between the two connecting contacts; determining the voltage of the line using the measured voltages; or b) within a server on a computing system remote from the sensor (such as for example, in a Cloud), the computing system comprising a microprocessor, and wherein the sensor transmits data to the server

As such, the present provides (in some embodiments) hardware: a voltage sensing unit for sensing a voltage of a power line using a single contact, the voltage sensing unit comprising: a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact; a line connector operatively connected to one of the two connecting contacts for operatively connecting the voltage sensing unit to the line; two voltage measuring contacts connected to the first connecting contact and the second connecting contact, the two voltage measuring contacts for receiving a voltage measuring unit.

In one aspect, within a fully computational voltage line sensor (sensing unit), the method steps of computing voltage at the power line within the electrical grid (as described further herein) occur.

In some variants of the invention, wherein it is desired that sensor hardware be simpler and not comprise some or all of the computational (processor) capabilities, the method steps of computing voltage at the power line within the electrical grid (as described further herein) occur on a processor remote from the sensor and to which the sensor transmits voltage data.

The present invention likewise provides (in some variants) computer implemented methods of computing voltage at a power line within an electrical grid, such methods being implemented either within the sensor or on a processor remote from the sensor and to which the sensor transmits one or both of i) raw voltage data or ii) processed voltage data, such methodologies being analogous, and in accordance with the steps and formulae provided herein, regardless.

In some variants of the invention, a method is provided of ascertaining an unknown line (conductor) voltage at point X on a power line within an electrical grid which comprises: a) collecting raw voltage at or about Point X1 using a sensor; b) gathering additional data from data collection sources upstream (comprising, for example a substation) and/or downstream (comprising, for example, one or more smart meters) to Point X1 (constraining data); c) using raw voltage, and environment and line data (comprising at least one of GPS location of sensor, GIS data of the electrical grid, phase, type of conductor, total load on conductor), to calculate voltage range at Point X1; and d) using constraining data sequentially to bind (narrow and tighten) the voltage range from a determined range of possibilities to a likely absolute voltage measurement.

The present invention provides, in some embodiments, a method for sensing a voltage of a power line using a single contact, the method comprising: providing a voltage sensing unit, the voltage sensing unit comprising a shielded enclosure hosting a bank of capacitors comprising at least two capacitors mounted in parallel, each of the at least two capacitors being controlled by a corresponding switch, the bank of capacitors having a first connecting contact and a second connecting contact; operatively connecting one of the two connecting contact of the voltage sensing unit to the line; for each given capacitor of the at least two capacitors; selecting the given capacitor using a corresponding switch; measuring a corresponding voltage between the two connecting contacts; determining the voltage of the line using the measured voltages.

The present invention provides, in some embodiments, a system for sensing a voltage of a power line using a single contact on the line, which comprises: a) a voltage sensing unit for sensing a voltage of a power line using a single contact, the voltage sensing unit comprising: a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact; a line connector operatively connected to one of the two connecting contacts for operatively connecting the voltage sensing unit to the line; two voltage measuring contacts connected to the first connecting contact and the second connecting contact, the two voltage measuring contacts for receiving a voltage measuring unit; b) a means to calibrate the at least two capacitors; c) a microcontroller circuit; d) a transceiver; e) storage memory for data; and f) a means to communicate voltage data.

The present invention provides, in some embodiments, a method for sensing a voltage of a power line using a single contact, the method comprising: providing a voltage sensing unit (the sensor), the voltage sensing unit comprising a shielded enclosure hosting a bank of capacitors comprising at least two capacitors mounted in parallel, each of the at least two capacitors being controlled by a corresponding switch, determining an unknown stray capacitance between a neutral conductor and the sensor (Cg) by measuring a set of voltages corresponding to differing switch positions and fitting measurements so determined to a non-linear circuit model.

The present invention provides, in some embodiments, a method for sensing a voltage of a power line using a single contact, the method comprising: providing a fully computational voltage sensing unit, the voltage sensing unit comprising a shielded enclosure hosting a bank of resistors comprising at least two resistors mounted in parallel, each of the at least two resistors being controlled by a corresponding switch, determining an unknown stray capacitance between a neutral conductor and the sensor (Cg) by measuring a set of voltages corresponding to differing switch positions and fitting measurements so determined to a non-linear circuit model.

The present invention provides, in some embodiments, a method for sensing a voltage of a power line using a single contact, the method comprising: providing a voltage sensing unit (comprising one or more sensors), the voltage sensing unit comprising a shielded enclosure hosting a bank of capacitors and/or resistors comprising at least two capacitors and/or resistors mounted in parallel, each of the at least two capacitors and/or resistors being controlled by a corresponding switch, determining an unknown stray capacitance between a neutral conductor and the sensor (Cg) by measuring a set of voltages corresponding to differing switch positions and fitting measurements so determined to a non-linear circuit model.

The sensor, voltage measuring methods, calibration methods and system of (various embodiments of) the present invention afford many advantages. Various embodiments described herein provide a way to make accurate voltage measurements using a protocol that only requires a sensor to have one contact with one conductor. The parasitic capacitance of the sensor to a second conductor is used to create a second reference which enables potential to be measured between the conductors. The parasitic capacitance from the sensor to the second conductor is referred to herein as Cg. This capacitance is highly variable and depends on the spacing of the wires and the placement and orientation of the sensor. The capacitance Cg is also dependent on environmental conditions which create movement in the wires (wind) and the thermal expansion of the wires which changes wire sag.

As such, some variants of this invention comprise one or more calibration method(s) used to determine the parasitic capacitance Cg. An accurate calibration method to determine Cg is critical to obtaining extremely accurate voltage measurements and such methods are described fully herein.

An elegant and simple method is provided herein to accurately measure voltage using a single contact to one conductor. The sensor comprises a sensing plate which couples to the second conductor through Cg. The sensor is guarded by a shield. Enclosed within this shield is a bank of calibrated capacitors which can be switched in to change the capacitor divide ratio. Using a calibrated and shielded capacitor bank provides a way to make accurate voltage measurements without knowing any of the physical parameters in the system such as conductor spacing and the distance to earth ground. The voltage sensor also is easily deployable in any field situation. The single contact improves the safety of deploying the sensor and avoids making contact between two conductors which is required in other voltage measurement methods.

The detailed description that follows is represented largely in terms of processes and symbolic representations of operations by computer components adapted from existing techniques as explained below. In some variants such components may include a processor, memory storage devices for the processor, and connected display devices and input devices. Furthermore, some of these processes and operations may (optionally) interact with or otherwise utilize conventional computer components in a heterogeneous distributed computing environment, including remote file servers, computer servers and memory storage devices.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured. The algorithms and displays with the applications described herein are not inherently related to any particular computer or other apparatus. Various general-purpose systems may be used with programs in accordance with the teachings herein, or it may prove convenient to construct more specialized apparatus to perform the required machine-implemented method operations. The required structure for a variety of these systems will appear from the description below. In addition, embodiments of the present invention are not described with reference to any particular programming language. It will be appreciated that a variety of programming languages may be used to implement the teachings of embodiments of the invention as described herein. One or more embodiments of the invention may be implemented as a method or as a machine readable non-transitory storage medium that stores executable instructions that, when executed by a data processing system, causes the system to perform a method. A sensor, connected to or in communication with an apparatus, such as a data processing system, can also be one or more embodiments of the invention. Other features of the present invention will be apparent from the accompanying drawings and from the detailed description which follows.

It is intended that the terminology used in the description presented below be interpreted in its broadest reasonable manner, even though it is being used in conjunction with a detailed description of certain example embodiments. Although certain terms may be emphasized below, any terminology intended to be interpreted in any restricted manner will be overtly and specifically defined as such.

The phrases “in some embodiments,” “in various embodiments,” “in some embodiments,” and the like are used repeatedly. Such phrases do not necessarily refer to the same embodiment. The terms “comprising,” “having,” and “including” are synonymous, unless the context dictates otherwise.

“Absolute,” “accurate,” “associated,” “at,” “at least,” “based,” “before,” “calculated,” “characterized,” “closed,” “corresponding,” “counterpart,” “determined,” “differing,” “distinct,” “downstream,” “each,” “electrical,” “environmental,” “field,” “flat,” “having,” “high-voltage,” “in parallel,” “insofar that,” “invoked,” “likely,” “likewise,” “line,” “linked,” “local,” “measured,” “mobile,” “more,” “mounted,” “near,” “neutral,” “nominal,” “observational,” “occurred,” “of,” “on the order of,” “open,” “other,” “parasitic,” “particular,” “physical,” “positioned,” “possible,” “present,” “protected,” “raw,” “recorded,” “related,” “remaining,” “rendered,” “second,” “semi-spherical,” “sensing,” “sequential,” “single,” “single,” “such as,” “switching,” “tapered,” “thereafter,” “third,” “to,” “transistor-based,” “unknown,” “uploaded,” “upstream,” “using,” “whole,” “within,” or other such descriptors herein are used in their normal yes-or-no sense, not merely as terms of degree, unless context dictates otherwise. In light of the present disclosure those skilled in the art will understand from context what is meant by “near” and by other such positional descriptors used herein. Terms like “processor,” “center,” “unit,” “computer,” or other such descriptors herein are used in their normal sense, in reference to an inanimate structure. Such terms do not include any people, irrespective of their location or employment or other association with the thing described, unless context dictates otherwise. “For” is not used to articulate a mere intended purpose in phrases like “circuitry for” or “instruction for,” moreover, but is used normally, in descriptively identifying special purpose software or structures. “On the order of” or “within an order of magnitude of” refer to values that differ by at most a factor of ten.

Reference is now made in detail to the description of the embodiments as illustrated in the drawings. While embodiments are described in connection with the drawings and related descriptions, there is no intent to limit the scope to the embodiments disclosed herein. On the contrary, the intent is to cover all alternatives, modifications and equivalents. In alternate embodiments, additional devices, or combinations of illustrated devices, may be added to, or combined, without limiting the scope to the embodiments disclosed herein.

Transistor-based circuitry as described herein may comprise an event-sequencing structure generally as described in U.S. Pat. Pub. No. 2015/0094046 but configured as described herein. Such circuitry may include one or more instances of modules configured for local processing, for example, each including an electrical node set upon which informational data is represented digitally as a corresponding voltage configuration. In some variants, moreover, an instance of such modules may be configured for invoking such local processing modules remotely in a distributed implementation. Event detection circuitry as described herein may likewise include one or more instances of modules configured for programmatic response as described below, for example, each including an electrical node set upon which informational data is represented digitally as a corresponding voltage configuration. In some variants, an instance of modules may be configured for invoking such programmatic response modules remotely in a distributed implementation.

In the interest of concision and according to standard usage in information management technologies, the functional attributes of modules described herein are set forth in natural language expressions. It will be understood by those skilled in the art that such expressions (functions or acts recited in English, e.g.) adequately describe structures identified below so that no undue experimentation will be required for their implementation. For example, any raw expressions or other informational data identified herein may easily be represented digitally as a voltage configuration on one or more electrical nodes (conductive pads of an integrated circuit, e.g.) of an event-sequencing structure without any undue experimentation. Each electrical node is highly conductive, having a corresponding nominal voltage level that is spatially uniform generally throughout the node (within a device or local system as described herein, e.g.) at relevant times (at clock transitions, e.g.). Such nodes (lines on an integrated circuit or circuit board, e.g.) may each comprise a forked or other signal path adjacent one or more transistors. Moreover many Boolean values (yes-or-no decisions, e.g.) may each be manifested as either a “low” or “high” voltage, for example, according to a complementary metal-oxide-semiconductor (CMOS), emitter-coupled logic (ECL), or other common semiconductor configuration protocol.

In some contexts one skilled in the art will recognize an “electrical node set” as used herein in reference to one or more electrically conductive nodes upon which a voltage configuration (of one voltage at each node, for example, with each voltage characterized as either high or low) manifests a yes/no decision or other digital data. A few of the electrical nodes thereof provide external connectivity (for power or ground or input signals or output signals, e.g.) via bonding wires, not shown. Significant blocks of integrated circuitry on an integrated circuit chip include special-purpose modules (comprising a sensor or other hard-wired special-purpose circuitry as described below, e.g.); and different structures of memory (volatile or non-volatile, e.g.) interlinked by numerous signal-bearing conduits (each comprising an internal node, e.g.) and otherwise configured as described below. As used herein “transistor-based circuitry” refers at least to very numerous transistors each having a control terminal (a gate or base, e.g.) and two end terminals linked in a network of signal-bearing conduits (forked or other serpentine signal traces, e.g.) according to intricate circuit designs like those described herein.

Although machine language instructions are written as sequences of binary digits, in actuality those binary digits specify physical reality. For example, if certain semiconductors are used to make the operations of Boolean logic a physical reality, the apparently mathematical bits “1” and “0” in a machine language instruction actually constitute a shorthand that specifies the application of specific voltages to specific wires. For example, in some semiconductor technologies, the binary number “1” (e.g., logical “1”) in a machine language instruction specifies around +5 volts applied to a specific “wire” (e.g., metallic traces on a printed circuit board) and the binary number “0” (e.g., logical “0”) in a machine language instruction specifies around −5 volts applied to a specific “wire.” In addition to specifying voltages of the machines' configurations, such machine language instructions also select out and activate specific groupings of logic gates from the millions of logic gates of the more general machine. Thus, far from abstract mathematical expressions, machine language instruction programs, even though written as a string of zeros and ones, specify many, many constructed physical machines or physical machine states.

The term “e.g.” and like terms mean “for example,” and thus does not limit the term or phrase it explains. For example, in a sentence “the computer sends data (e.g., instructions, a data structure) over the Internet,” the term “e.g.” explains that “instructions” are an example of “data” that the computer may send over the Internet, and also explains that “a data structure” is an example of “data” that the computer may send over the Internet. However, both “instructions” and “a data structure” are merely examples of “data,” and other things besides “instructions” and “a data structure” can be “data.”

The term “respective” and like terms mean “taken individually.” Thus if two or more things have “respective” characteristics, then each such thing has its own characteristic, and these characteristics can be different from each other but need not be. For example, the phrase “each of two machines has a respective function” means that the first such machine has a function and the second such machine has a function as well. The function of the first machine may or may not be the same as the function of the second machine.

The term “i.e.” and like terms mean “that is,” and thus limits the term or phrase it explains. For example, in the sentence “the computer sends data (i.e., instructions) over the Internet,” the term “i.e.” explains that “instructions” are the “data” that the computer sends over the Internet.

The term “voltage sensing unit” is used interchangeably herein with “sensor” and “voltage sensor.” It is to be understood that two different types of voltage sensors are described for use with the methods herein: one is a simple line sensor (with few if any processing or computational abilities) and which collects and transmits to a remote server, raw voltage information. It is at the remote server that the raw voltage data is combined with other data, preferably with constraints, to calculate actual voltage at a selected point on an electrical power line. The other sensor described herein is referred to interchangeably as a “fully computational sensor.” Not only does this sensor collect raw voltage data, it optionally collects and aggregates other data and, in accordance with the methods described herein, calculates actual voltage at a selected point on an electrical power line. The simple line sensor offloads some or all computation functions to a remote server/processor.

The fully computational sensor offloads little if any of the processing steps. Preferably, the latter sensor comprising: a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact; a line connector operatively connected to one of the two connecting contacts for operatively connecting the voltage sensing unit to the line; two voltage measuring contacts connected to the first connecting contact and the second connecting contact, the two voltage measuring contacts for receiving a voltage measuring unit; b) a means to calibrate the at least two capacitors; c) a microcontroller circuit; d) a transceiver; e) storage memory for data; and f) a means to communicate voltage data.

Preferably, an exemplary flat metal plate is used as the sensing plate to couple to the electric field between the non-contacted wire and the sensor. Capacitance Cg is the capacitance between the non-contacted wire and the sensing plate. There are many possible types of sensing plate within the scope of the invention. Examples include a metal plate on a post that positions the sensing plate away from the body of the sensor. In this configuration, Cg can be increased while decreasing Co. The shape of the sensing plate can also vary. For example, the plate may be conical, spherical, semi-spherical, or tapered. A flat sensing disk on a post has been found to provide a good compromise between maximizing Cg which is important for accuracy and the disk is also easy to implement and manufacture.

Any given numerical range shall include whole and fractions of numbers within the range. For example, the range “1 to 10” shall be interpreted to specifically include whole numbers between 1 and 10 (e.g., 1, 2, 3, 4, . . . 9) and non-whole numbers (e.g. 1.1, 1.2, . . . 1.9).

Where two or more terms or phrases are synonymous (e.g., because of an explicit statement that the terms or phrases are synonymous), instances of one such term/phrase does not mean instances of another such term/phrase must have a different meaning. For example, where a statement renders the meaning of “including” to be synonymous with “including but not limited to,” the mere usage of the phrase “including but not limited to” does not mean that the term “including” means something other than “including but not limited to.”

Neither the Title (set forth at the beginning of the first page of the present application) nor the Abstract (set forth at the end of the present application) is to be taken as limiting in any way as the scope of the disclosed invention(s). An Abstract has been included in this application merely because an Abstract of not more than 150 words is required under 37 C.F.R. section 1.72(b). The title of the present application and headings of sections provided in the present application are for convenience only, and are not to be taken as limiting the disclosure in any way.

Numerous embodiments are described in the present application, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural and logical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

No embodiment of method steps or product elements described in the present application constitutes the invention claimed herein, or is essential to the invention claimed herein, or is coextensive with the invention claimed herein, except where it is either expressly stated to be so in this specification or expressly recited in a claim.

The invention can be implemented in numerous ways, including as a method, an apparatus, a system, a computer readable medium such as a computer readable storage medium or a computer network wherein program instructions are sent over optical or communication links. In this specification, these implementations, or any other form that the invention may take, may be referred to as systems or techniques. A component such as a processor or a memory described as being configured to perform a task includes both a general component that is temporarily configured to perform the task at a given time or a specific component that is manufactured to perform the task. In general, the order of the steps of disclosed processes may be altered within the scope of the invention.

While not intending to be limiting, there are three main case scenarios for voltage measuring and for which the methods and sensors of the invention are particularly useful: (A) Rural parts of the world where no sub-station measurement equipment exists and no smart meters exist at the end of a line feeder; (B) Regions where sub-station has measurement equipment, but there are no downstream measuring points available (e.g. no smart meters) (C) Regions (generally First World or Western regions) where sub-station and homes/business have measurement equipment (Smart meters at the homes/businesses).

Within the framework of the above three case scenarios, the following are favorable computational structures (i.e. where voltage computation can be done): (1) Voltage computation is done on the Sensor—Scenario A above; (2) Voltage computation is done remote from the sensor (for example in the Cloud)—Scenario B or C above; (3) Voltage computation is done remote from sensor—Scenario C above.

Use Case A: Sensor Operates Independently

A method of computing voltage at a power line within an electrical grid wherein there is no substation, no downstream (end of line feeder) measuring means (e.g. one or more smart meters)—and wherein computation of voltage is achieved within a fully computational voltage sensing unit, as a single contact on the power line, the method comprises: (a) collecting a sampled signal from power line (Vm) using a sensor, the sensor comprising a sensing plate which couples to a second conductor through Cg (parasitic capacitance from the sensor to the second conductor), the sensor being guarded by a shield within which is a bank of calibrated capacitors; (b) switching calibrated capacitors to change a capacitor divide ratio; and (c) calculating voltage at sensor.

In this way, the sampled signal (Vm) is processed locally in the actual sensor unit and applies factory calibration as well as estimates of Cg using predetermined constraints on the admissible range for Cg and the line voltage. The sensor unit then transmits/sends calibration voltage, current and power factor measurements back to a remote site, a central monitoring site. Reference to “remote site” simply means “not on sensor” but otherwise an application that runs on a server at a location. This location may be behind a user's firewall or at a data center like Rackspace, etc . . . .

“Cloud” simply refers to refers to a computing hardware machine or group of computing hardware machines commonly referred as a server connected through a communication network such as the Internet, an intranet, a local area network (LAN) or wide area network (WAN).

The following describes variants of the invention, wherein unit samples sensor signals and sends the raw measurements back to a central monitoring site. The central monitoring site would know the location of the sensor and apply factory calibration for the unit and determine Cg and VL using a constrained nonlinear optimizer. In other words, the processing of raw data is done remotely. This may have an advantage if a log of raw data is to be captured.

Use Case B: Additional Substation Data Available e.g. Substation Voltage

In this embodiment, substation voltage may be used to set a constraint for the optimization algorithm. For example, the line voltage in the distribution grid could be used as an upper bound for the estimated line voltage at the sensor.

In this embodiment, wherein there is a substation with voltage measuring capacity but no downstream (end of feeder) voltage measuring means (e.g. one or more smart meters)—and wherein computing of voltage is achieved as follows. A method of computing voltage at a power line within an electrical grid comprises i) collecting data in a voltage sensing unit on the power line (such as, for example, a simple voltage gathering sensor, and which need not necessarily be a fully computational voltage sensing unit); ii) transmitting data to a server on a computing system remote from the sensor (such as for example, in a Cloud), the computing system comprising a microprocessor; and iii) additional structure as follows.

With the fast development of cloud computing and high speed wireless technologies, it has become feasible to offload computing to the cloud infrastructure servers, e.g., remote cloud servers such as Amazon EC2™ (elastic computer cloud) or local cloud servers such as nearby desktops. Herein, knowing information from the GIS, one can calculate what V should be at the location of one of the sensors, knowing, for example, conductor type size, and rating and the like . . . .

Preferably a “remote” or “cloud based software platform” connects to a SCADA (Supervisory Control And Data Acquisition) system and possibly also to a GIS system. The software would then have the ability to determine if there are any other sensors connected to the SCADA system within the grid, and poll these sensors through the SCADA system for additional voltage information. If no other devices exist in the grid, then it would be able to poll the monitoring equipment located in the sub-station. We can collect raw-measurements with the sensor, send this back to the cloud software.

Use Case C Substation and Smart Meter Data

Within this embodiment, substation and smart meter data may be used to provide more accurate bounds on the actual line voltage at the sensor point. The accuracy of the estimation of line voltage is improved by tightening the constraint on the limits for V.sub.L.

The processor may receive data from a GIS system from a SCADA system, from an MDM (Meter Data Management) system and/or from Head-End Smart Meter data collection system. In any event, in a preferred aspect, smart metering and other data is transmitted to the processor.

Smart meters are located at the end-points of the consumer, whether it be a residential or industrial consumer. These smart meters are capable of collecting Voltage (V), Current (I), Reactive Power (VAR), and sometimes Power Factor (pf). Knowing information from the GIS what V should be can be calculated at the location of one of the sensors, wherein the conductor type size, and rating are known. In this case, Case C above, a calculation is done upstream to the sensor. In Case C, a calculation may be done downstream to the sensor. That is, the voltage at the sensor in Case B will be lower than the measurement point of the sub-station, and higher than the measurement point of the smart meter in this case, Case C. Ideally, it is important to know the GIS information. It is not required to obtain information from the smart meter itself directly, but access to data can be achieved through another means,for example either the MDM or a Head-End Smart Meter data collection system that shares the smart metering information with many applications. In both Case B & C, this additional V and VAR information will allow calculation of energy (kWh) to a much higher accuracy (the ultimate goal).

The measurements that come from either the sub-station, or the smart meter, or both (blend of Case B & C) will computation of the voltage measurement remotely (for example, in the Cloud), passing raw measurement data from the sensors to the cloud, and setting boundary conditions on what this V measurement could and should be based on the data collected from the various other points on the grid. To reiterate, these other points can be: the substation monitoring equipment, smart meters, or other sensors and devices located within the distribution grid.

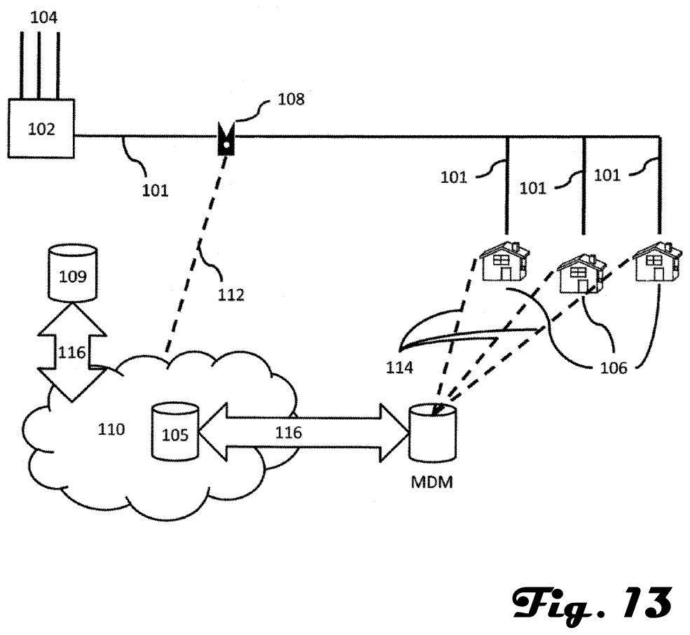

Scenario C-3 is described with reference to FIG. 13. In this case, an electrical grid shown generally at 100 having line 101 has both an upstream measurement source (substation) 102, monitoring/metering equipment at the sub-station 104 and a downstream source 106, the smart meter(s) at the home or business.

Sensor 108 is are placed on the electrical grid, at location(s) with known GPS coordinates. From the GIS data of the electrical grid, the phase is understood, as well as the type of conductor, and the total load that is on that conductor.

A simple voltage sensor collects raw voltage measurements at that location. These raw measurements are transmitted to a remote processor in the cloud 110 (i.e. one or more computer networks) for computation. To constrain this computation to obtain and absolute voltage measurement at any given point, and to accurately computer voltage over time, additional data from the downstream source 106 and the upstream source 102 is captured and transmitted to processor 105 in cloud 110. There may be only one upstream source, but most likely there will be multiple downstream sources.

Since the location of the sensor is known, and information about the electrical grid like the type of conductor and load is known, mathematical models can be used to calculate what the voltage should be at the given point (Point X1) of the sensor. A derived value is used to constrain the voltage measurement calculations such that a true absolute voltage measurement is obtained. This method and system offloads the computation from the sensor into a remote processor, and utilizes additional data from the grid to more accurately compute the voltage measurement. This method can also be applied to calculating reactive power in the same manner.

The present disclosure relates to voltage sensors and use for high-voltage power line monitoring. Such a measurement sensor has not previously been identified with only one point of contact with the power line. As previously noted, the advantages of this are significant. In order to implement this method, there is herein provided methods of calibration of the sensor in order to obtain accurate voltage measurements (over the one point of contact).

Two types of calibration are described: (1) field calibration to determine Cg; and (2) factory calibration to determine Co, C.sub.m, R.sub.m . . . .

The value of Cg depends on the physical arrangement of the conductors and the orientation of the sensor. Factors which affect the physical arrangement of the conductors are temperature, (wire sag) and the movement or sway of the conductors in the wind.

Field calibration if preferably achieved by collecting a series of measurements with “different” combinations of capacitors selected in the capacitor bank. Such measurements are then used to solve a non-linear system of equations based on Equation (2). For field calibration, the unknowns are Cg and V.sub.L (the line voltage).

Factory calibration is, in one preferred aspect, used to determine Co, C.sub.m and R.sub.m. In the factory, a test bed with known line voltages can be used to make a series of measurements of Vm under different switch conditions in the capacitor bank. These measurements are then used to find a best fit for Equation 2. Similar to field calibration, this step requires solving a system of nonlinear equations. Various well known numerical methods can be used to solve the equations and include, but are not limited to Newton's method and the Nelder-Mead root finder algorithm.

Some variants describe herein are configured to calibrate a sensor where an unknown stray capacitance between a neutral conductor and the sensor (Cg) is determined by measuring a set of voltages corresponding to a set of capacitor bank switch positions. The set of measurements are then fitted to a nonlinear circuit model to estimate Cg .

Some variants are likewise configured to calibrate a sensor where Cg is determined by measuring a set of voltages corresponding to a set of resistor bank switch positions. The set of measurements are then fitted to a nonlinear circuit model to estimate Cg.

Some variants are likewise configured to calibrate a sensor where Cg is determined by measuring a set of voltages corresponding to a set of capacitor and resistor bank switch positions. The set of measurements are then fitted to a nonlinear circuit model to estimate Cg.

Some variants are likewise configured to use one of the calibration methods together with a model of the sensor, wherein an output voltage is measured which corresponds to the line voltage.

Some variants are likewise configured to use a voltage measurement combined with a current measurement and wherein the power factor of the line is thereby determined.

Some variants are likewise configured to use a three-phase measurement method which uses three single contact voltage sensors.

Some variants are likewise configured to combine measurements of the three voltage sensors in a three-phase measurement system (preferably at a remote site) to measure the voltage of each phase.

Some variants are likewise configured to use measurements of three single contact voltage sensors in a three-phase measurement system and combine such measurements (preferably at a remote site) to measure power factor for each phase. In some variants of the invention, data may (optionally) be collected from one or more sensors and communicated over a wireless network allowing utility companies to quickly and economically detect losses within their electrical power grid.

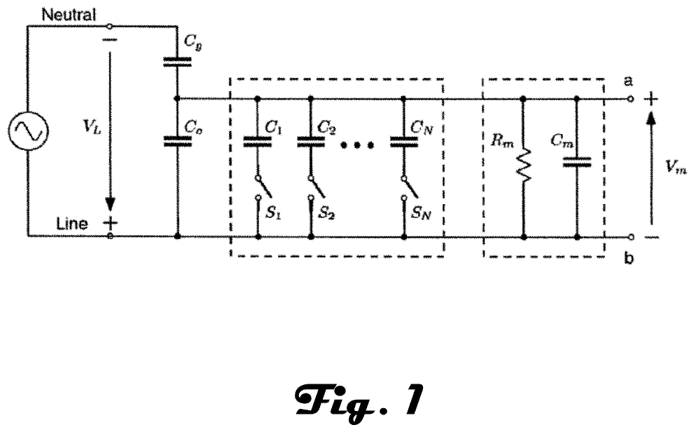

Referring now to FIG. 1, there is shown a circuit model for a single contact voltage measurement. In the circuit model as shown, the following circuit elements are defined:

Cg: an unknown stray capacitance between the neutral conductor and the sensor

C₀: the intrinsic capacitance of the sensor without the capacitor bank

C.sub.1; C.sub.2; : : : ; C.sub.N: a bank of calibrated capacitors which are switch into the circuit to make voltage measurements

R.sub.m and C.sub.m: the load impedance presented by the measurement buffer amplifier which contributes an error to the measured voltage Vm

In this context it is possible to make an accurate voltage measurement of the line voltage V.sub.L by measuring Vm. The measurement can be made providing all values of the components listed above are known. However, the capacitance Cg depends on the specific location where the sensor is installed and must be determined by a field calibration process. Also, Cg may vary over time due to changes in wire sag from temperature or from movement created by swaying conductors. The other component values in the model for C₀, the capacitor bank, and the measurement resistance and capacitance can be determined by a factory calibration procedure.

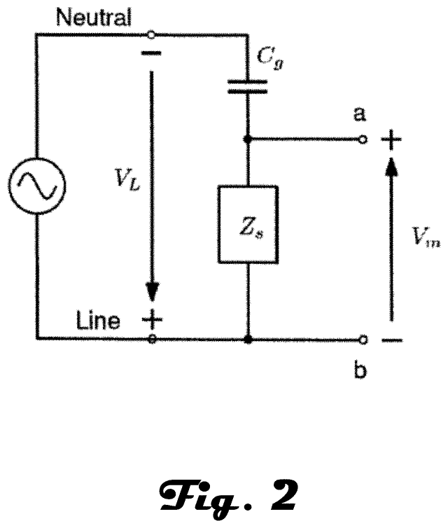

The capacitor bank components are expected to be precise capacitors with known temperature coefficients and may not require—additional calibration through a factory calibration procedure. Therefore, methods for both field and factory calibration are expected in a preferred embodiment of the sensor design. Consider the case where a factory calibration method has been employed and the values of C₀, C.sub.1; C.sub.2; : : : ; C.sub.N, R.sub.m, and C.sub.m are all known. The remaining unknown value is Cg which must be determined by a field calibration procedure. A method of determining Cg is described next which is based on a set of measurements which are taken by changing the effective capacitance of the sensor by switching in different combinations of capacitors in the capacitor bank. A description of the field calibration procedure begins with an analysis of the circuit model shown in FIG. 1. An equivalent circuit can be derived from the model in FIG. 1 by replacing the shunt arrangement of C₀, the capacitor bank, and the measurement impedance with a single sensor impedance Z.sub.s. The simplified model is shown in FIG. 2. The impedance Z.sub.s can be expressed as the inverse of the admittance Y.sub.s where

$${Y}_{s} = \frac{1}{{R}_{m}} + jω ( {C}_{o} + {C}_{b} + {C}_{m} ) . \qquad ( 1 )$$

In equation (1), the capacitance C.sub.b is the total effective capacitance of the capacitor bank and depends on the state of the switches in the bank. The measured voltage Vm relates to the line voltage V.sub.L through an impedance divider created by Cg and Z.sub.s:

$${V}_{m} = - {V}_{L} \frac{{Z}_{s}}{{Z}_{s} + 1 / ( jω {C}_{g} )} = - {V}_{L} \frac{jω {C}_{g}}{jω {C}_{g} + {Y}_{s}} \qquad ( 2 )$$

Equation (1) can be used in equation (2) for Y.sub.s to give:

$${V}_{m} = - {V}_{L} \frac{jω {C}_{g}}{1 / {R}_{m} + jω ( {C}_{o} + {C}_{b} + {C}_{m} + {C}_{g} )} . \qquad ( 3 )$$

Further manipulation of equation (3) yields:

$${V}_{m} = - {V}_{L} \{ \begin{matrix}\frac{{ω}^{2} {C}_{g} ( {C}_{o} + {C}_{b} + {C}_{m} + {C}_{g} )}{{( 1 / {R}_{m} )}^{2} + {[ ω ( {C}_{0} + {C}_{b} + {C}_{m} + {C}_{g} ) ]}^{2}} + \\ \frac{jω {C}_{g} / {R}_{m}}{{( 1 / {R}_{m} )}^{2} + {[ ω ( {C}_{o} + {C}_{b} + {C}_{m} + {C}_{g} ) ]}^{2}}\end{matrix} \} \qquad ( 4 )$$

Equation (4) shows that the measured voltage corresponds to a scaled line voltage V.sub.L with an additional phase shift that depends on the effective loading resistance of the measurement amplifier R.sub.m. The operation of the sensor is seen more clearly if R.sub.m is assumed to be very large relative to the capacitive reactances in the circuit. In the limit as R.sub.m.goes to infinity:

$${V}_{m} = - {V}_{L} \frac{{C}_{g}}{{C}_{o} + {C}_{b} + {C}_{m} {C}_{g}} . \qquad ( 5 )$$

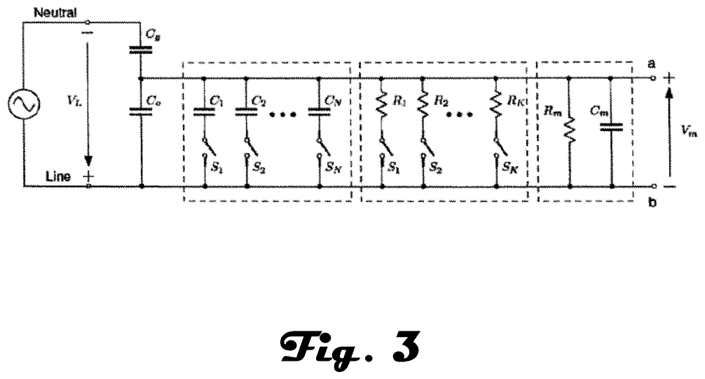

Under this condition, the circuit reduces to a capacitive voltage divider. The capacitance Cg is typically very small in the range of 1-pF or less and the bank capacitance C.sub.b can be selected to provide a voltage division ratio so that Vm is—smaller than V.sub.L. As an example, suppose a voltage division ratio of 30—is listed as a requirement. If Cg is 1 pF, C₀ is 10 pF, and C.sub.m is 10 pF, then the capacitance in the switch bank is 9 pF. Equation (4) shows that in general when the measurement resistance R.sub.m of the instrumentation amplifier introduces a phase error between the measured voltage Vm and the line voltage V.sub.L. The change in phase error as a function of a change in the capacitance C.sub.b of the capacitor bank provides additional information which can improve the estimate of Cg . Since only the magnitude of Vm is measured, the magnitude is a function of both the real and imaginary parts in equation (4). If R.sub.m, C.sub.m, Co, and C.sub.1; C.sub.2; : : : CN are all known through factory calibration, then R.sub.m introduces additional warping in the nonlinear function which improves the accuracy of fitting a Cg to the measurement data. An extension of this idea is to add a resistor switch bank as shown in FIG. 3. With a resistor switch bank, additional measurements can be collected which correspond to different resistor bank settings. The measurements can then provide additional information for determining a best fit of Cg for the sensor model.

With reference to equation (5), in a practical application of the sensor unit it is preferred to know the value of C₀+C.sub.m within a reasonably tight tolerance. This is because fits of Vm versus C.sub.b data to equation (5) cannot be used to uniquely determine all three of V.sub.L, Cg , C₀. Rather fits to equation (5) determine only the product V.sub.L*Cg and the sum C₀+C.sub.m+Cg . If C₀+C.sub.m is known accurately from a previous factory calibration, then it is possible to determine the line voltage V.sub.L.

With reference to equation (5), the accuracy of the sensor is dependent on the relative ratio of Cg over the sum of Co, C.sub.m and C.sub.b. The ratio (Cg/(Co+C.sub.m+C.sub.b) is preferably maximized for maximum accuracy. In a typical application, a series of measurements are made with different values of bank capacitance C.sub.b. From the series of measurements, an estimate is then made for Cg and the unknown line voltage V.sub.L assuming C₀ and C.sub.m have been calibrated at the factory. Since there are two unknowns, the best fit depends on maximizing the resolution of the function to the value of Cg because Cg affects the degree of nonlinearity in equation (5) which in turn affects the accuracy of estimated values for Cg and the line voltage. The more nonlinear equation (5) is the better the accuracy.

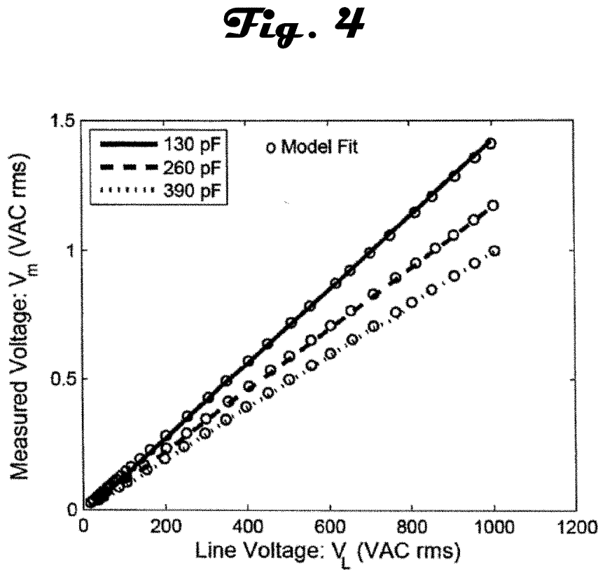

An example of measurements made with a calibrated voltage sensor is shown in FIG. 4. In this embodiment, the capacitor bank consists of three 130 pF capacitors. Measurements were first made with S.sub.1 closed (130 pF), then S.sub.2 was closed (260 pF), and finally all three switches were closed (390 pF). From these measurements, a nonlinear fit was made to the model is equation (4). The data in FIG. 4 shows a comparison between experimental measurements of Vm with the model in equation (4) as a function of line voltage. The match between the sensor voltage and the model is very good and demonstrates how accurate voltage measurements using the single-contact sensor and method of the present invention can be.

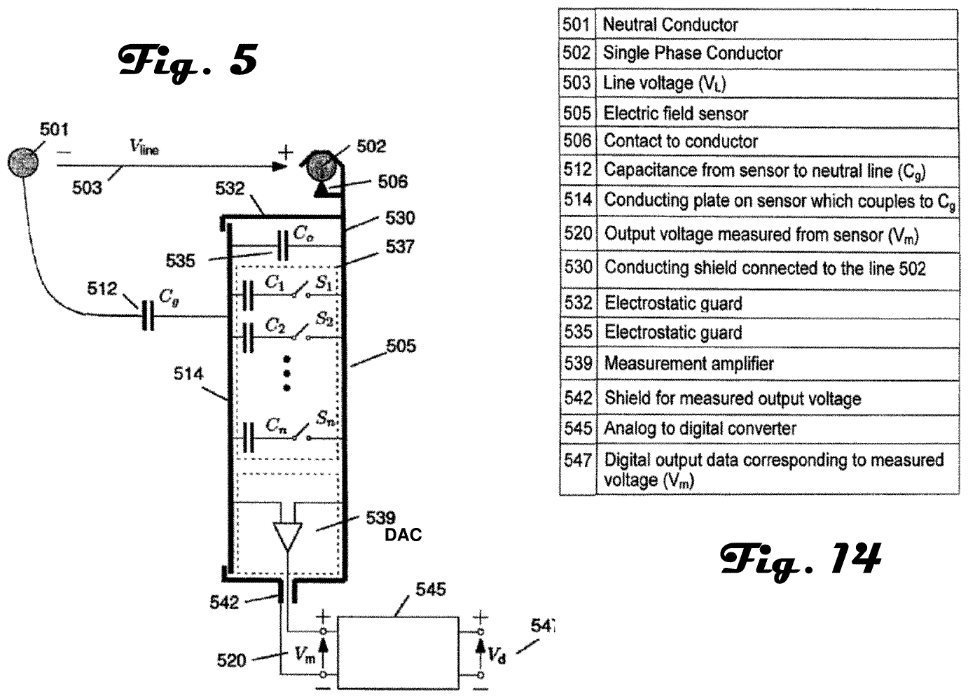

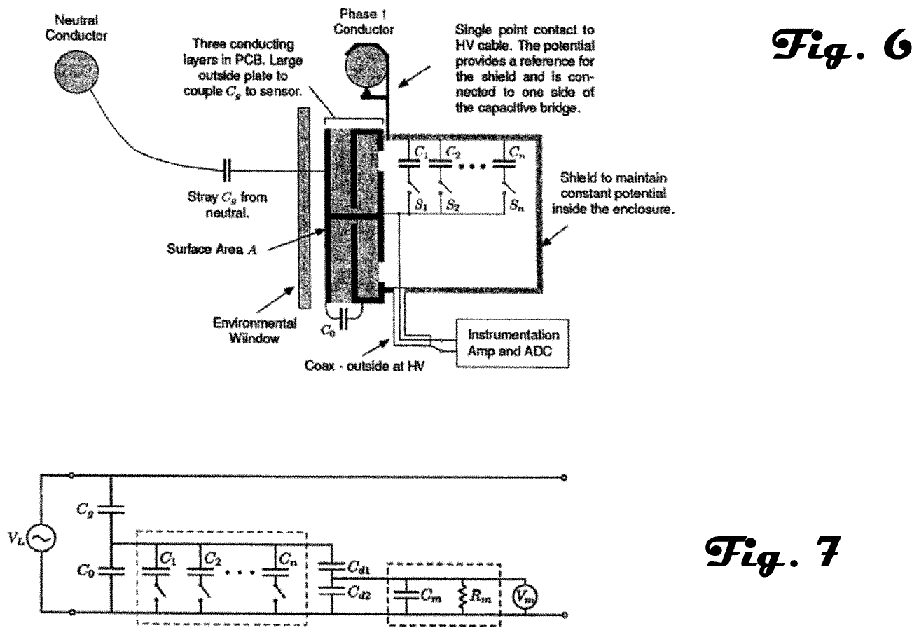

With reference to FIGS. 5 and 6, an exemplary flat metal plate is used as the sensing plate to couple to the electric field between the non-contacted wire and the sensor. Capacitance Cg is the capacitance between the non-contacted wire and the sensing plate. There are many possible types of sensing plate within the scope of the invention. Examples include a metal plate on a post that positions the sensing plate away from the body of the sensor. In this configuration, Cg can be increased while decreasing Co. The shape of the sensing plate can also vary. For example, the plate may be conical, spherical, semi-spherical, or tapered. A flat sensing disk on a post has been found to provide a good compromise between maximizing Cg which is important for accuracy and the disk is also easy to implement and manufacture.

In high-voltage applications, a multistage capacitive divider can be advantageous. This is illustrated in FIG. 7. Provided that C.sub.d1 is selected to be comparable to C.sub.m in equation (5) and C.sub.d2 is much greater than C.sub.d1, the ratio between the line voltage V.sub.L and the measured voltage Vm can be made arbitrarily large without compromising the sensitivity of single point contact voltage sensor. With the additional capacitive divider formed by C.sub.d1 and C.sub.d2 in place and in the limit R.sub.m.rarw..infin., the full expression relating Vm to V.sub.L is:

$${V}_{m} = {V}_{L} [ \frac{{C}_{g}}{{C}_{0} + {( \frac{1}{{C}_{d 1}} + \frac{1}{{C}_{d 2} + {C}_{m}} )}^{- 1} + {C}_{b} + {C}_{g}} ] \times ( \frac{{C}_{d 1}}{{C}_{d 1} + {C}_{d 2} + {C}_{m}} ) \qquad ( 6 )$$

In the limit that C.sub.d2>>C.sub.d1 equation (6) simplifies to:

$${V}_{m} \approx {V}_{L} ( \frac{{C}_{g}}{{C}_{0} + {C}_{b} + {C}_{d 1} + {C}_{g}} ) \frac{{C}_{d 1}}{{C}_{d 2}} \qquad ( 7 )$$

Comparing equation (7) to equation (5) shows that the additional capacitive divider does not change the sensitivity of the voltage sensor provided that C.sub.d1.apprxeq.C.sub.m, but reduces Vm by a factor of C.sub.d1/C.sub.d2<<1 which is desirable for high-voltage applications to avoid saturating the unity gain buffer.

The capacitive divider may be extended to more than two steps for very high voltage applications.

Software Architecture for Remote Sensing Units-Details

In accordance with some variants of the invention, a single contact voltage sensor is a component in a remote monitoring unit which is suspended from a high voltage transmission line wire. The unit is also configured with a current sensor. Voltage and current waveforms can be simultaneously sampled to calculate power factor, another very important measurement which utility companies require to monitor the reactive power in the grid. Other measurements which can be made by post-processing raw sensor data include the harmonic content in the waveforms to calculate total harmonic distortion. Voltage and current signals should be sinusoidal, but in practice there are harmonic frequency components. The level of the harmonics should be low and require monitoring in the grid.

The voltage and current sensors provide analog signals which are sampled by an analog to digital converter (ADC). After sampling, digital representations of the voltage and current signals are available for further processing. The ADC has a sample rate which is much higher than the line frequency (for example 50 or 60 Hz) and each signal is captured as a times series. For example, N samples from the voltage and current sensors can be captured and stored as a time series with additional information including a time stamp and the location of the sensor. It should be noted that ideally the voltage and current signals are captured simultaneously by synchronized ADCs. This ensures that there is no phase error between the voltage and current waveforms. If a multiplexed ADC is used, the timing of samples needs to be controlled and post-processing can then be used to realign the raw voltage and current sensor waveforms.

After capturing records (time series) of voltage and current data from the sensors, post-processing is required to transform the data into useful outputs which an operator of a utility will want to monitor. Examples of post-processed outputs include the voltage of each phase at the monitoring point, the current in each phase at the monitoring point, the power factor at the monitoring point, and the total harmonic distortion of the voltage and current waveforms. Post-processing can be done either remotely in the remote monitor unit or in a cloud based server. The cloud based server could either be located at the central monitoring site or it may be a service provided by another vendor.

The central monitoring site for a utility consolidates sensor data from many sources including remote monitor units located in the distribution and transmission grid, smart meters at loads, and substation monitoring units. The entire set of sensor data available at the central monitoring site can provide valuable information which can be used to assist in constraining unknown parameters which are required to interpret the raw sensor data accurately. The additional sensor information available at the central monitoring site can be either uploaded to a remote monitoring unit to improve the accuracy of processing sensor data, or, the raw sensor data can be downloaded to a server in the central monitoring station and processed by software that uses data from multiple monitoring points in the network. Therefore, sensor data can be processed independently (e.g. from a single remote monitoring unit) or collectively where data from many sensors are consolidated to improve the accuracy of measurements at specific points in the grid.

Scenarios: Independent and Local Processing vs. Remote Processing

Multiple sensor data which is consolidated at a remote server that then uploaded constraints which improve the accuracy of post-processing sensor data in a remote unit. For example, data from the remote sensor is combined with substation monitoring data and/or smart meter data from end user loads.

Multiple sensor data which is consolidated at a remote server that is applied to raw sensor data logs which have been uploaded from remote units. For example, data substation monitoring data and/or smart meter data from end user loads is used to provide constraints which are uploaded to the remote unit which improves the accuracy of estimating the line voltage.

The network scenarios described above can be considered examples of system requirement specification. The system requirements are used to design the software architecture for remote sensing unit with the single point contact voltage sensor. An example of the high-level design requirements for the software is described below.

Simultaneously capture N samples of the output signals from the voltage sensor (Vm) and the current sensor (Im). The raw sensor data is consolidated into a record which includes the value of the bank capacitance Cb, the current temperature of the sensor, the time base for the samples, the location of the sensor and the serial number of the sensor.

A series of data logs is created by stepping through different values of bank capacitance (Cb). The line voltage is assumed to be constant as the bank capacitance is stepped through different values. Therefore, the latency between each step is small.

Each sensor unit has factory calibration data associated with it that includes the value of Co, the value of bank capacitances and temperature calibration data. The calibration data can be stored locally in the remote sensor, or stored remotely on a server, or mirrored in both the remote unit and on a remote server.

A programmable flag whose state is set by the central monitoring site determines whether raw sensor data logs are uploaded to the remote server or whether the remote unit should process the raw sensor data. Therefore, depending on the state of this flag, it determines where the next steps in the software flow are executed: locally or remotely.

A set of constraint ranges is associated with each unknown variable which needs to be estimated. In the voltage sensor two unknowns are the stray capacitance Cg to the non-contacted line and the unknown line voltage of the phase which is being monitored. The constraints provide bounds for each unknown variable which must be estimated using a nonlinear optimization algorithm. The accuracy of the estimated values depends on the constraint ranges. A tight bound on the range of a variable improves the accuracy of the estimated value.

Constraint ranges for Cg and the line voltage VL are predetermined by the location of the sensor in the grid. The constraint ranges can be programmed remotely from the central office or preset during installation.

The predetermined constraint ranges for unknown variables (e.g. Cg and VL) may be updated using additional sensor data in the grid. For example, substation voltage measurements could be used to set the upper bound on the line voltage assuming the remote sensor is located between the substation and the end user load. The voltage at the monitoring point must be less than the substation voltage assuming there are no other local generating sites feeding the distribution grid. Another adjustment on the constraint range for the line voltage could be obtained using smart meters which monitor the voltage at the end of the distribution grid. Smart meter voltage measurements could be used to set the lower bound on the line voltage which is to be estimated by the remote voltage sensor.

A nonlinear constrained optimization algorithm is used to estimate the line voltage at the location of the remote sensor unit. The inputs to the algorithm include the raw data log files for a set of bank capacitances, the temperature, the value of Co, the constraint range for Cg, and the constraint range for the line voltage. The optimizer then iterates to minimize an error function and provide estimates of Cg and the line voltage. The optimizer is either run locally in the remote unit if the remote flag is set, or it is run on a remote server.

After a line voltage is estimated, it can be combined with processed current data to estimate the power factor and the total harmonic distortion. In one aspect, the system additionally comprises one or more network managers. Preferably, these one or more network managers which each comprise a modem capable of transmitting measurement data from the sensor over a network.

In one aspect, the system additionally comprises one or more network managers which relay data from the sensors to a server via a communication channel such as cellular, satellite, WiMAX and Wifi. In one aspect, the system may additionally comprise one or more network managers that aggregate and relay the data from the sensors to a server and wherein the server enables viewing of the data by a viewer via an interface. In one aspect, the system additionally comprises one or more network managers which aggregate and relay the data from the sensors to a server and wherein the server enables viewing of the data by a viewer via an interface and wherein the interface is selected from the group consisting of a desktop computer, a laptop computer, a hand-held microprocessing device, a tablet, a Smartphone, iPhone™, iPad™, PlayBook™ and an Android™ device.

Those skilled in the relevant art will appreciate that some variants of the invention can be practiced with various computer configurations, including hand-held devices, multiprocessor systems, microprocessor-based or programmable consumer electronics, personal computers (“PCs”), network PCs, mini-computers, mainframe computers, and the like. In one aspect, the measurement data is communicated wirelessly on a peer-to-peer network to a central network manager. In one aspect, the measurement data is collected in situ from the sensors or network managers. This can be achieved by workers on site either on the ground or using a bucket truck. In one aspect, the system comprises more than three sensors. In one aspect, the system may be temporarily field deployable on one or more supply line electrical wires and then moved and reset on other supply line electrical wires without the requirement of any wire splicing for such deployment and re-deployment.

In one aspect, the method additionally employs one or more network managers. In one aspect, the method additionally employs one or more network managers which each comprise a modem which transmits measurement data over a network. In one aspect, the method additionally employs one or more network managers which relay data from the sensor nodes to a server via a means selected from the group consisting of cellular, satellite, WiMAX and Wifi. In one aspect, the method additionally employs one or more network managers which aggregate and relay the data from the sensor nodes to a server and wherein the server enables viewing of the data by a viewer via an interface. In one aspect, the method additionally employs one or more network managers which aggregate and relay the data from the sensor nodes to a server and wherein the server enables viewing of the data by a viewer via an interface and wherein the interface is selected from the group consisting of a desktop computer, a laptop computer, a hand-held microprocessing device, a tablet, a Smartphone, iPhone™, iPad™, PlayBook™ and an Android™ device. Those skilled in the relevant art will appreciate that some variants of the invention can be practiced with various computer configurations, including hand-held devices, multiprocessor systems, microprocessor-based or programmable consumer electronics, personal computers (“PCs”), network PCs, mini-computers, mainframe computers, and the like. In one aspect, measurement data is communicated wirelessly on a peer-to-peer network to a central network manager. In yet another aspect, the measurement data is collected in situ from the sensor nodes or network managers. This may be achieved by workers on site either on the ground or using, for example, a bucket truck. In yet another aspect, the method uses more than three sensor nodes. In another aspect, the sensors for use in the method may be temporarily field deployable on one or more supply line electrical wires and then moved and reset on other supply line electrical wires without the requirement of any wire splicing for such deployment and re-deployment. In yet another aspect, the measurement data is transmitted wirelessly to a server; and an analysis is made to determine if a loss has occurred. In another aspect, the supply line electrical wire is a medium voltage line or a high voltage line.

In operation, if the data acquired using the sensors, system and/or method of the invention indicates possible power loss, flaws, voltage leakages or other problems, notification may be sent to a monitoring entity or to a utility. The sensors are easy to deploy electrical distribution line sensors, which, once engaged at the single point of contact, may instantly begin to relay measurement data back to central servers for post processing through the network manager (Gateway), which itself is also mobile like the measurement sensors. The entire system can be expanded, contracted, and relocated at will. Furthermore, in some variants of the invention, there is provided enterprise software which allows users a real time dashboard with powerful analytics to help them consume large amounts of field measurement data in an effective manner.

Preferably, the sensors communicate using open standards (using for example, IEEE802.15.4) as demanded by the utility industry. Each node within the system is capable of wirelessly hopping data from a sister sensor to the end of the router device. Sensors can be placed in close proximity to one another or alternatively can be placed at distances from one another.

Within the scope of the present invention, data acquisition may preferably be controlled by a computer or microprocessor. As such, the invention can be implemented in numerous ways, including as a process, an apparatus, a system, a computer readable medium such as a computer readable storage medium or a computer network wherein program instructions are sent over optical or communication links. In this specification, these implementations, or any other form that the invention may take, may be referred to as systems or techniques. A component such as a processor or a memory described as being configured to perform a task includes both a general component that is temporarily configured to perform the task at a given time or a specific component that is manufactured to perform the task. In general, the order of the steps of disclosed processes may be altered within the scope of the invention.

The following discussion provides a brief and general description of a suitable computing environment in which various embodiments of the system may be implemented. In particular, this is germane to the network managers, which aggregate measurement data and downstream to the servers which enables viewing of the data by a user at an interface.

Although not required, embodiments will be described in the general context of computer-executable instructions, such as program applications, modules, objects or macros being executed by a computer. Those skilled in the relevant art will appreciate that the invention can be practiced with other computer configurations, including hand-held devices, multiprocessor systems, microprocessor-based or programmable consumer electronics, personal computers (“PCs”), network PCs, mini-computers, mainframe computers, and the like. The embodiments can be practiced in distributed computing environments where tasks or modules are performed by remote processing devices, which are linked through a communications network. In a distributed computing environment, program modules may be located in both local and remote memory storage devices.

A computer system may be used as a server including one or more processing units, system memories, and system buses that couple various system components including system memory to a processing unit. Computers will at times be referred to in the singular herein, but this is not intended to limit the application to a single computing system since in typical embodiments, there will be more than one computing system or other device involved. Other computer systems may be employed, such as conventional and personal computers, where the size or scale of the system allows. The processing unit may be any logic processing unit, such as one or more central processing units (“CPUs”), digital signal processors (“DSPs”), application-specific integrated circuits (“ASICs”), etc. Unless described otherwise, the construction and operation of the various components are of conventional design. As a result, such components need not be described in further detail herein, as they will be understood by those skilled in the relevant art. A computer system includes a bus, and can employ any known bus structures or architectures, including a memory bus with memory controller, a peripheral bus, and a local bus. The computer system memory may include read-only memory (“ROM”) and random-access memory (“RAM”). A basic input/output system (“BIOS”), which can form part of the ROM, contains basic routines that help transfer information between elements within the computing system, such as during startup. The computer system also includes non-volatile memory. The non-volatile memory may take a variety of forms, for example a hard disk drive for reading from and writing to a hard disk, and an optical disk drive and a magnetic disk drive for reading from and writing to removable optical disks and magnetic disks, respectively. The optical disk can be a CD-ROM, while the magnetic disk can be a magnetic floppy disk or diskette. The hard disk drive, optical disk drive and magnetic disk drive communicate with the processing unit via the system bus. The hard disk drive, optical disk drive and magnetic disk drive may include appropriate interfaces or controllers coupled between such drives and the system bus, as is known by those skilled in the relevant art. The drives, and their associated computer-readable media, provide non-volatile storage of computer readable instructions, data structures, program modules and other data for the computing system. Although a computing system may employ hard disks, optical disks and/or magnetic disks, those skilled in the relevant art will appreciate that other types of non-volatile computer-readable media that can store data accessible by a computer system may be employed, such a magnetic cassettes, flash memory cards, digital video disks (“DVD”), Bernoulli cartridges, RAMs, ROMs, smart cards, etc.

Various program modules or application programs and/or data can be stored in the computer memory. For example, the system memory may store an operating system, end user application interfaces, server applications, and one or more application program interfaces (“APIs”).

The computer system memory also includes one or more networking applications, for example a Web server application and/or Web client or browser application for permitting the computer to exchange data with sources via the Internet, corporate Intranets, or other networks as described below, as well as with other server applications on server computers such as those further discussed below. The networking application in the preferred embodiment is markup language based, such as hypertext markup language (“HTML”), extensible markup language (“XML”) or wireless markup language (“WML”), and operates with markup languages that use syntactically delimited characters added to the data of a document to represent the structure of the document. A number of Web server applications and Web client or browser applications are commercially available, such those available from Google and Microsoft.

The operating system and various applications/modules and/or data can be stored on the hard disk of the hard disk drive, the optical disk of the optical disk drive and/or the magnetic disk of the magnetic disk drive.

A computer system can operate in a networked environment using logical connections to one or more client computers and/or one or more database systems, such as one or more remote computers or networks. A computer may be logically connected to one or more client computers and/or database systems under any known method of permitting computers to communicate, for example through a network such as a local area network (“LAN”) and/or a wide area network (“WAN”) including, for example, the Internet. Such networking environments are well known including wired and wireless enterprise-wide computer networks, intranets, extranets, and the Internet. Other embodiments include other types of communication networks such as telecommunications networks, cellular networks, paging networks, and other mobile networks. The information sent or received via the communications channel may, or may not be encrypted. When used in a LAN networking environment, a computer is connected to the LAN through an adapter or network interface card (communicatively linked to the system bus). When used in a WAN networking environment, a computer may include an interface and modem or other device, such as a network interface card, for establishing communications over the WAN/Internet.

In a networked environment, program modules, application programs, or data, or portions thereof, can be stored in a computer for provision to the networked computers. In one embodiment, the computer is communicatively linked through a network with TCP/IP middle layer network protocols; however, other similar network protocol layers are used in other embodiments, such as user datagram protocol (“UDP”). Those skilled in the relevant art will readily recognize that these network connections are only some examples of establishing communications links between computers, and other links may be used, including wireless links.

While in most instances, a computer will operate automatically, where an end user application interface is provided, a user can enter commands and information into the computer through a user application interface including input devices, such as a keyboard, and a pointing device, such as a mouse. Other input devices can include a microphone, joystick, scanner, etc. These and other input devices are connected to the processing unit through the user application interface, such as a serial port interface that couples to the system bus, although other interfaces, such as a parallel port, a game port, or a wireless interface, or a universal serial bus (“USB”) can be used. A monitor or other display device is coupled to the bus via a video interface, such as a video adapter (not shown). The computer can include other output devices, such as speakers, printers, etc.

It is to be fully understood that the many of the methods, systems and devices presented herein also may be implemented as a computer program product that comprises a computer program mechanism embedded in a computer readable storage medium. For instance, the computer program product could contain program modules. These program modules may be stored on CD-ROM, DVD, magnetic disk storage product, flash media or any other computer readable data or program storage product. The software modules in the computer program product may also be distributed electronically, via the Internet or otherwise, by transmission of a data signal (in which the software modules are embedded) such as embodied in a carrier wave.

For instance, the foregoing detailed description has set forth various embodiments of the devices and/or processes via the use of examples. Insofar as such examples contain one or more functions and/or operations, it will be understood by those skilled in the art that each function and/or operation within such examples can be implemented, individually and/or collectively, by a wide range of hardware, software, firmware, or virtually any combination thereof. In one embodiment, the present subject matter may be implemented via ASICs. However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof, and that designing the circuitry and/or writing the code for the software and or firmware would be well within the skill of one of ordinary skill in the art in light of this disclosure.

In addition, those skilled in the art will appreciate that the mechanisms taught herein are capable of being distributed as a program product in a variety of forms, and that an illustrative embodiment applies equally regardless of the particular type of signal bearing media used to actually carry out the distribution. Examples of signal bearing media include, but are not limited to, the following: recordable type media such as floppy disks, hard disk drives, CD ROMs, digital tape, flash drives and computer memory; and transmission type media such as digital and analog communication links using TDM or IP based communication links (e.g., packet links).

While the forms of node/apparatus, method and system described herein constitute preferred embodiments of this invention, it is to be understood that the invention is not limited to these precise forms. As will be apparent to those skilled in the art, the various embodiments described above can be combined to provide further embodiments. Variants of the present systems, methods and nodes (including specific components thereof) can be modified, if necessary, to best employ the systems, methods, nodes and components and concepts of the invention. These variants are considered fully within the scope of the invention as claimed. For example, the various methods described above may omit some acts, include other acts, and/or execute acts in a different order than set out in the illustrated embodiments.

Further, in the methods taught herein, the various acts may be performed in a different order than that illustrated and described. Additionally, the methods can omit some acts, and/or employ additional acts.

### EXAMPLE 1

### Measuring Voltage

The sensor voltage is measured across the external capacitance between nodes A and B. The voltage is buffered by a high-input impedance voltage follower using an Intersil CA3140 op-amp. The op-amp uses two nine volt batteries providing supply voltages of +/−9 V where the common mode voltage is referenced to the line voltage (hot conductor). The output of the buffer is connected to an Agilent DVM model 34401A which is used to record the sensor voltage. Since the DVM loads the sensor, the measurement model preferably includes compensation for Rm and Cm, the effective input resistance and capacitance of the meter. For this example, Rm is 10 Mohm and Cm is 370 pF. The DVM has analog to digital converters (ADC's) which are floating relative to the potential of the high voltage line. The maximum differential voltage between the input of the meter and ground (neutral) is rated for 500 VAC. This limitation can be removed using an optocoupler.

Three silver mica 130 pF capacitors are used for the calibrated shunt capacitances C.sub.1, C.sub.2, and C.sub.3. For the first set of experimental data, the C.sub.1 is 130 pF and a series of measurements are made for different input voltages ranging from 10 VAC to 130 VAC. The corresponding voltages generate a vector of voltage values called V1. After the first set of sensing voltages V1 are made, two additional sets of measurements are made with C.sub.1 plus C.sub.2, and C.sub.1 plus C.sub.2 plus C.sub.3, respectively. The corresponding sensor voltages are called V2 and V3. The measurement results are tabulated in Table I.

TABLE I
MEASURED SENSING VOLTAGES
FOR DIFFERENT CAPACITANCES.

| Vᵢₙ (V) | V₁ (V) | V₂ (V) | V₃ (V) |
|---|---|---|---|
| 10 | 0.177 | 0.1385 | 0.1074 |
| 20.2 | 0.363 | 0.2733 | 0.21929 |
| 30.1 | 0.5429 | 0.4083 | 0.3274 |
| 40 | 0.7236 | 0.5439 | 0.4359 |
| 50.1 | 0.9075 | 0.6815 | 0.5469 |
| 60 | 1.085 | 0.619 | 0.6559 |
| 70.1 | 1.2712 | 0.957 | 0.7627 |
| 80 | 1.436 | 1.1 | 0.86 |
| 90 | 1.61 | 1.215 | 0.97 |
| 100 | 1.819 | 1.374 | 1.0924 |
| 110.2 | 2.004 | 1.5011 | 1.2042 |
| 120 | 2.1876 | 1.646 | 1.3122 |
| 130.1 | 2.3698 | 1.775 | 1.4229 |

### EXAMPLE 2

### Linearity Test

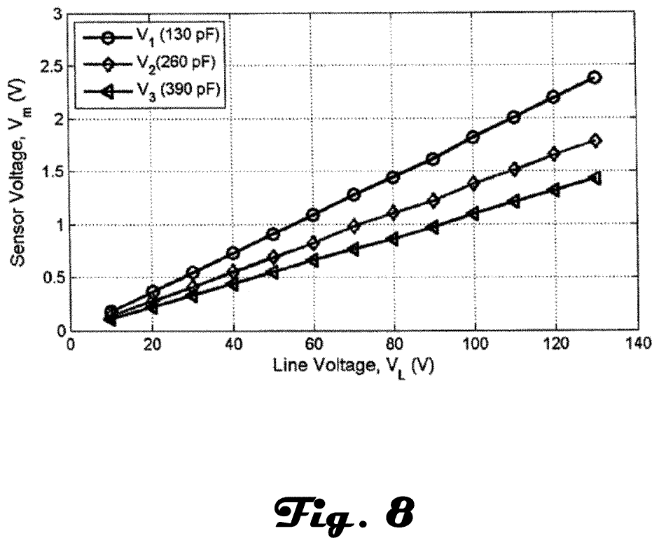

To check the linearity of the measured sensing voltages, a figure is plotted based on input voltages versus sensing voltages. This is shown graphically in FIG. 8. From this figure, it is clear that the sensing voltages, V1, V2 and V3 are linear.

### EXAMPLE 3

### Factory Calibration to Estimate the Unknown Capacitances

A numerical method is developed to solve for the unknown values (C₀, Cg, and V.sub.L) by applying three parallel capacitances successively across the voltage sensor on the high-voltage line. This numerical method has been implemented in Matlab code to validate the measurement method. If the first capacitance C.sub.1 is connected across C₀, then the voltage V1 from node A to node B can be calculated from the following equation: It is to be noted that the high impedance buffer removes the contribution of C.sub.m and the input capacitance of the buffer, from hereon, is assumed to be absorbed in the value of C₀.

$${V}_{1} = {V}_{L} \frac{{C}_{g}}{{C}_{g} + {C}_{0} + C} . \qquad ( 1 )$$

Similarly, if the second and third capacitances are connected, the corresponding voltages V2 and V3 are:

$$\begin{matrix}{V}_{2} = {V}_{in} \frac{{C}_{g}}{{C}_{g} + {C}_{0} + 2 C} & ( 2 ) \\ {V}_{3} = {V}_{in} \frac{{C}_{g}}{{C}_{g} + {C}_{0} + 3 C} & ( 3 ) \\ {V}_{2} = {V}_{L} \frac{{C}_{g}}{{C}_{g} + {C}_{0} + 2 C} & \\ {V}_{3} = {V}_{L} \frac{{C}_{g}}{{C}_{g} + {C}_{0} + 3 C} . & \\ {V}_{2} = {V}_{L} \frac{{C}_{g}}{{C}_{g} + {C}_{0} + 2 C} & ( 2 ) \\ {V}_{3} = {V}_{L} \frac{{C}_{g}}{{C}_{g} + {C}_{0} + 3 C} . & ( 3 )\end{matrix}$$

By simplifying equation 1 to 3 the following is attained:

V₁C_{g}−VᵢₙC_{g}+V₁Cₒ+V₁CO (4)

V₂C_{g}−VᵢₙC_{g}+V₂Cₒ+2V₂C=0 (5)

V₃C_{g}−VᵢₙC_{g}+V₃Cₒ+3V₃C=0. (6)

V₁C_{g}−V_{L}C_{g}+V₁Cₒ+V₁C=0

V₂C_{g}−V_{L}C_{g}+V₂Cₒ+2V₂C=0

V₃C_{g}−V_{L}C_{g}+V₃Cₒ+3V₃C=0.

V₁C_{g}−V_{L}C_{g}+V₁Cₒ+V₁C=0 (4)

V₂C_{g}−V_{L}C_{g}+V₂Cₒ2V₂C=0 (5)

(7=0, (6)

In equation (4), (5) and (6), the measured (detected) voltages V1, V2, V3 and the external capacitances are known. Therefore, in these equations there are three unknowns, Cg, C₀ and V.sub.L. These three equations are non-linear and cannot be used to uniquely solve for the three unknown variables. However if, as in a factory calibration, a known line voltage V.sub.L is applied to the system the values of Cg and C₀ can be uniquely determined preferably by using a root finder algorithm and a mean square error (MSE) objective function. For example, a root finder algorithm—may be used in this case and initial estimates for the unknown values are provided. The objective function is nonlinear with local minima and selecting appropriate initial values is generally desired in order to get convergence to the global minimum. By using equation (4), (5) and (6) and the measured sensing voltages from Table I, values for Cg and C₀ can be found. The estimated values of Cg, and C₀ from Matlab are tabulated in Table II.

TABLE II
ESTIMATED VALUES

| Vᵢₙ (V) | C_{g} (pF) | C₀ (pF) |
|---|---|---|
| 10 | 7.1842 | 266.6186 |
| 20.2 | 7.0680 | 259.6052 |
| 30.1 | 7.0815 | 257.8584 |
| 40 | 7.1374 | 256.7471 |
| 50.1 | 7.1500 | 256.9363 |
| 60 | 7.1094 | 260.5893 |
| 70.1 | 7.0644 | 253.4807 |
| 80 | 7.0584 | 253.5380 |
| 90 | 7.0466 | 257.5662 |
| 100 | 6.9778 | 254.8648 |
| 110.2 | 7.0367 | 254.0642 |
| 120 | 7.1688 | 253.0786 |
| 130.1 | 7.0631 | 253.3477 |

The mean of the estimated values for C₀ and Cg are 257 pF and 7.1 pF respectively. The standard deviation of the estimated values for C₀ and Cg are 3.9 pF and 0.06 pF, respectively, which are very reasonable. Therefore these measurements show that it is possible to conduct a factory calibration to determine the unknown capacitances Cg and C₀ and that the values of these capacitances are independent of the applied line voltage. The value of Cg is sensitive to the geometry of the conductors, for example the conductor spacing and the conductor height above ground. Because of this sensitivity, the value of Cg determined from the factory calibration may not be well matched to the value of Cg when the voltage sensing unit is deployed in the field. The value of C₀, however is much less sensitive to the conductor geometry and its the value in the field can be accurately estimated from a prior factory calibration.

### EXAMPLE 4

### Blind Estimates of Line Voltages

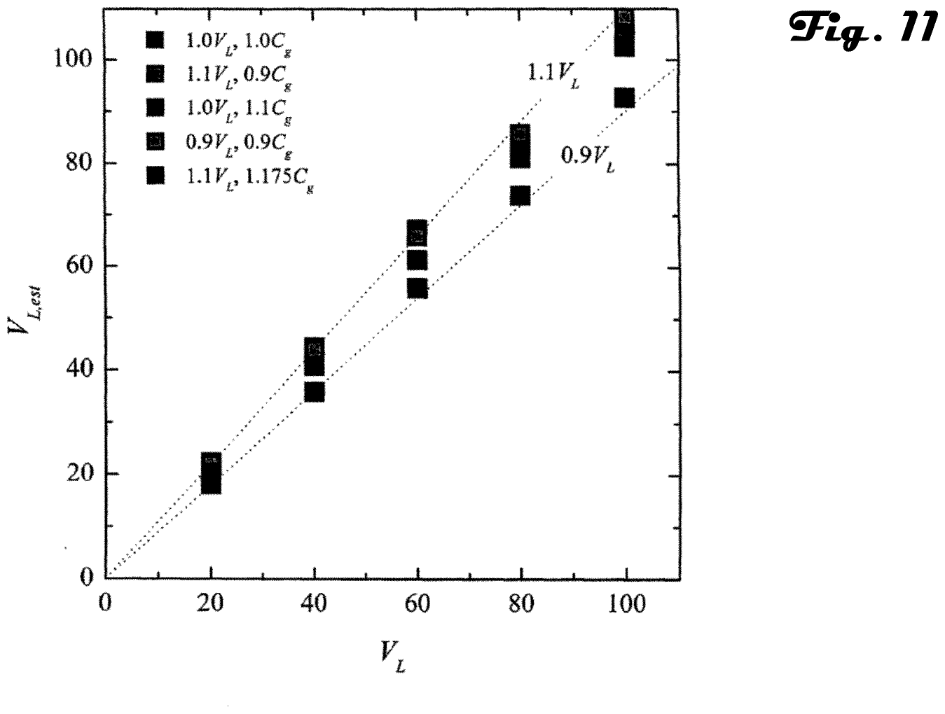

Having completed a prior factory calibration to accurately determine C₀, the only unknowns in equation (5) relating Vm to the V.sub.L are the line voltage V.sub.L and Cg . Non-linear fits of Vm measured as a function of C.sub.b fit to equation (5) will result in best-fit values of both Cg and V.sub.L. FIG. 11 compares the estimated line voltage determined using the voltage sensing unit to the known applied line voltage. In this example, C₀ was determined from a factory calibration to be 9.18 pF. Non-linear fits of the collected data to equation (5) Cg values close to 1.00 pF and estimated line voltages that were within 10% of the applied line voltages. The accuracy with which V.sub.L can be estimated is proportional to Cg/C₀ and to the accuracy with which C₀ is known. Therefore, it is crucial that both an accurate factory calibration be performed to determine C₀ and that the voltage sensing unit be designed such that Cg/C₀ be as small as is practical.

### EXAMPLE 5

### Linearity of the High-Voltage Configuration

With C₀=9.18 pF and Cg=1.00 pF as in Example 4 above, the line voltage is reduced by less than one tenth when C.sub.b is set to zero. As a result, modest line voltages of just over 100 Vrms would be sufficient to saturate the buffer of the voltage sensing unit making the device useless as a high-voltage sensor. In this example, an additional secondary capacitive divider was added as shown in FIG. 7 using the values C.sub.d1=0.5 pF and C.sub.d2=130 pF to further reduce Vm by a factor of 1/260 without altering the sensitivity of the sensor.

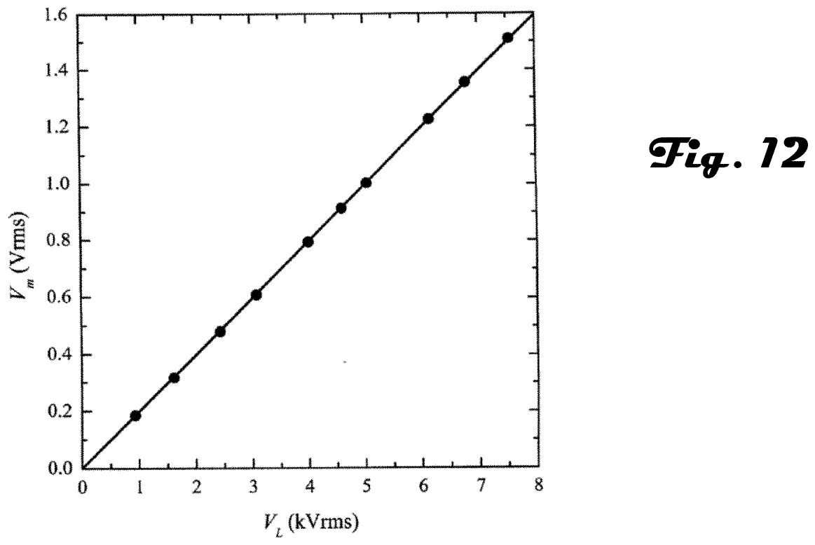

FIG. 12 shows the measured voltage Vm plotted as a function of the V.sub.L up to 7.5 kVrms. The obvious linear relationship shows that Vm is directly proportional to the line voltage as desired. Furthermore, the sensor buffer will not saturate until a line voltage of approximately 60 kVrms is reached. If even larger line voltages need to be measured, one simply has to use larger values of C.sub.d2. Increasing C.sub.d2 enables larger line voltages to be measured by does not alter the sensor sensitivity. These and other changes can be made to the present systems, methods and articles in light of the above description. In general, in the following claims, the terms used should not be construed to limit the invention to the specific embodiments disclosed in the specification and the claims, but should be construed to include all possible embodiments along with the full scope of equivalents to which such claims are entitled. Accordingly, the invention is not limited by the foregoing disclosure, but instead its scope is to be determined as set forth in the claims that follow.

FIG. 13 is an electrical grid schematic showing lines 101 to many structures to which one or more downstream voltage sources 106 are affixed. Alternatively or additionally one or more upstream sources 102 (relative to one or more temporarily placed sensors 108) may exist, operably coupled to a primary sub-station 104 as shown. One or more networks comprising cloud 110 may comprise one or more processors 105 and data repositories 109, configured as described herein to use data from a first sensor 108 in conjunction with models or other data. As shown processor 105 may control or be controlled by one or more interfaces 116 with a data repository 109 or other data-handling apparatuses (such as monitoring linkages 114 or one or more communication or control linkages 112 as shown.

In light of teachings herein, numerous existing techniques may be applied for configuring special-purpose circuitry or other structures effective for switching, model implementation, or other control or computation tasks as described herein without undue experimentation. See, e.g., U.S. Pat. No. 10,396,594 (“Single phase power factor correction system and method ”); U.S. Pat. No. 10,320,373 (“RF production using nonlinear semiconductor junction capacitance”); U.S. Pat. No. 9,876,388 (“System, method and device for providing a stable power source without the use of direct connection to an AC or DC source”); U.S. Pat. No. 8,977,738 (“Automated discovery of monitoring devices on a network”); U.S. Pat. No. 8,896,393 (“Coupling interfaces for communication transceivers over power lines”); U.S. Pat. No. 8,063,674 (“Multiple supply-voltage power-up/down detectors”); U.S. Pat. No. 7,902,854 (“Body capacitance electric field powered device for high voltage lines”); U.S. Pat. No. 7,282,944 (“Body capacitance electric field powered device for high voltage lines”); U.S. Pub. No. 20160069937 (“Voltage sensing unit for sensing voltage of high-power lines using a single-contact point and method of use thereof”); and U.S. Pub. No. 20140368183 (“System and method for linear measurement of ac waveforms with low voltage non-linear sensors in high voltage environments”). These documents are incorporated herein by reference to the extent not inconsistent herewith.

All of the patents and other publications referred to above are incorporated herein by reference generally—including those identified in relation to particular new applications of existing techniques—to the extent not inconsistent herewith. While various system, method, article of manufacture, or other embodiments or aspects have been disclosed above, also, other combinations of embodiments or aspects will be apparent to those skilled in the art in view of the above disclosure. The various embodiments and aspects disclosed above are for purposes of illustration and are not intended to be limiting, with the true scope and spirit being indicated in the final claim set that follows.

In the numbered clauses below, specific combinations of aspects and embodiments are articulated in a shorthand form such that (1) according to respective embodiments, for each instance in which a “component” or other such identifiers appear to be introduced (with “a” or “an,” e.g.) more than once in a given chain of clauses, such designations may either identify the same entity or distinct entities; and (2) what might be called “dependent” clauses below may or may not incorporate, in respective embodiments, the features of “independent” clauses to which they refer or other features described above.

### CLAUSES

1. A method for characterizing a power line within an electrical grid including characterizing an unknown line voltage at a first point X1 on the power line, the method comprising:

collecting raw voltage at or about the first point X1 using a first sensor;

gathering additional data from one or more data collection sources upstream to or downstream to the first point X1;

using raw voltage, and environment and line data to calculate a first voltage range at the first point X1; and

using constraining data to bind the first voltage range from a determined range of possibilities to a single voltage measurement.

2. The method of ANY one of the above method clauses, wherein there is a substation with voltage measuring capacity but no downstream voltage measuring mechanism in a proximity of the first voltage sensor (i.e. during an instance of the method being performed).

3. The method of ANY one of the above method clauses, wherein the raw voltage is collected in a voltage sensing unit at the first point X1 using a first sensor and wherein the voltage sensing unit comprises the first sensor.

4. The method of ANY one of the above method clauses, the method comprising:

transmitting the raw voltage data to a server on a computing system remote from the first sensor, the computing system comprising a first microprocessor.

5. The method of ANY one of the above method clauses, comprising:

configuring a voltage sensing unit comprising a shielded enclosure hosting a bank of capacitors or resistors (or both).

6. The method of ANY one of the above method clauses, comprising:

configuring a voltage sensing unit by mounting first and second loads thereof in parallel, each load comprising one or more capacitors or one or more resistors (or both).

7. The method of ANY one of the above method clauses, comprising:

configuring a voltage sensing unit by mounting first and second loads thereof in parallel, wherein each of the loads comprises one or more capacitors or one or more resistors and wherein each of the loads is controlled by a corresponding switch; and

(determining or otherwise) accounting for a stray capacitance (Cg) between a neutral conductor and the first sensor by measuring a set of voltages corresponding to differing positions of the switches and fitting measurements so determined to a non-linear circuit model.

8. The method of ANY one of the above method clauses, wherein the single voltage measurement is obtained with one instance of the first sensor being brought into contact once on the power line (i.e. during an entire performance of the method).

9. The method of ANY one of the above method clauses, wherein a parasitic capacitance is taken into account so as to mitigate error due to one or more environmental conditions that create movement in the wires (e.g. wind) or thermal expansion of the wires (or both).

10. The method of ANY one of the above method clauses, wherein a parasitic capacitance is taken into account so as to mitigate error due to one or more environmental conditions that create movement in the wires (of the power line) and wherein the parasitic capacitance drifts more than 0.5% (in magnitude) due to one or more wind gusts (e.g. exceeding 1 kilometer per hour).

11. The method of ANY one of the above method clauses, wherein a parasitic capacitance is taken into account so as to mitigate error due to one or more environmental conditions that create movement in the wires and wherein the parasitic capacitance drifts more than 0.5% due to thermal expansion of the wires (e.g. warming by more than 2 degrees Celsius).

12. The method of ANY one of the above method clauses, performed using a circuit model like that of FIG. 1.

13. The method of ANY one of the above method clauses, performed using a circuit model like that of FIG. 2.

14. The method of ANY one of the above method clauses, using a single-contact point voltage sensor comprising a switched capacitor bank and a switched resistor bank like that of FIG. 3.

15. The method of ANY one of the above method clauses, wherein the first sensor is calibrated like that of FIG. 4.

16. The method of ANY one of the above method clauses, performed using a circuit model like that of FIG. 5.

17. The method of ANY one of the above method clauses, performed using a circuit model like that of FIG. 6.

18. The method of ANY one of the above method clauses, performed using a circuit model with an additional capacitive voltage divider like that of FIG. 7.

19. The method of ANY one of the above method clauses, comprising: applying a linearity test like that of FIG. 8.

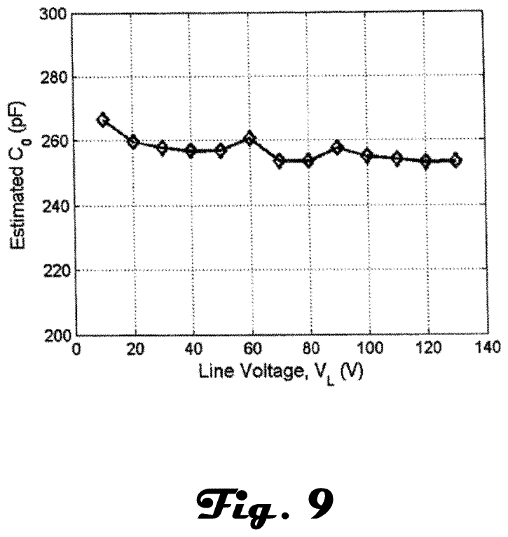

20. The method of ANY one of the above method clauses, wherein estimated capacitance C₀ varies as a function of an applied line voltage (e.g. like that of FIG. 9).

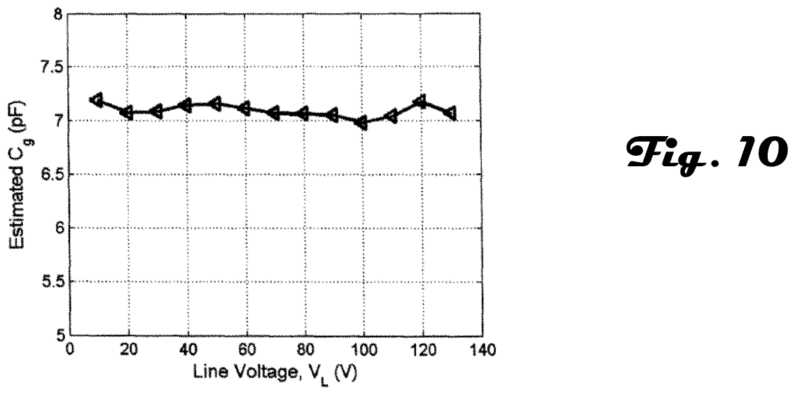

21. The method of ANY one of the above method clauses, wherein estimated capacitance Cg varies as a function of an applied line voltage (e.g. like that of FIG. 10).

22. The method of ANY one of the above method clauses, comprising:

sequentially using two or more different initial parameter values in a non-linear fit routine like that of FIG. 11.

23. The method of ANY one of the above method clauses, wherein a voltage sensing unit that includes the first sensor is configured to obtain high-voltage measurements using an additional secondary capacitive divider.

24. The method of ANY one of the above method clauses, wherein a voltage sensing unit is configured to obtain high-voltage measurements so as to approximate a linear relationship between Vm and V.sub.L as depicted in FIG. 12.

25. The method of ANY one of the above method clauses, implemented in an electrical grid like that of FIG. 13.

26. The method of ANY one of the above method clauses, implemented in relation to at least one upstream source 102 like that depicted in FIG. 13.

27. The method of ANY one of the above method clauses, implemented in relation to at least one downstream source 106 like that depicted in FIG. 13.

28. The method of ANY one of the above method clauses, wherein the using the raw voltage, and the environment and line data comprises:

transmitting the raw voltage data to a server on a computing system remote from the sensor (such as for example, in a Cloud), the computing system comprising a microprocessor, and wherein the raw voltage, and environment and line data comprises GPS sensor location.

29. The method of ANY one of the above method clauses, wherein the using the raw voltage, and the environment and line data comprises:

transmitting the raw voltage data to a server on a computing system remote from the sensor (such as for example, in a Cloud), the computing system comprising a microprocessor, and wherein the raw voltage, and environment and line data comprises GIS data of the electrical grid.

30. The method of ANY one of the above method clauses, wherein the using the raw voltage, and the environment and line data comprises:

transmitting phase and conductor type data to a server on a computing system remote from the sensor (such as for example, in a Cloud), the computing system comprising a microprocessor; and

receiving the first voltage range or the constraining data from the server based on the raw voltage, and the environment and line data.

31. The method of ANY one of the above method clauses, wherein the using the raw voltage, and the environment and line data comprises:

transmitting total load on conductor data to a server on a computing system remote from the sensor (such as for example, in a Cloud), the computing system comprising a microprocessor; and

receiving the first voltage range or the constraining data from the server based on the raw voltage, and the environment and line data; and

receiving the first voltage range or the constraining data from the server based on the raw voltage, and the environment and line data.

32. The method of ANY one of the above method clauses, wherein the raw voltage is collected in a voltage sensing unit at the first point X1 using a first sensor and wherein the voltage sensing unit comprises the first sensor, the method comprising

transmitting the raw voltage data to a server on a computing system remote from the first sensor, the computing system comprising a microprocessor.

33. The method of ANY one of the above method clauses, wherein the unknown line voltage at the first point X1 is sensed using a single contact, the method comprising:

providing a voltage sensing unit, the voltage sensing unit comprising a shielded enclosure hosting a bank of resistors comprising at least two resistors mounted in parallel, each of the at least two resistors being controlled by a corresponding switch, and determining an unknown stray capacitance between a neutral conductor and the voltage sensing unit by measuring a set of voltages corresponding to differing switch positions and fitting measurements so determined to a non-linear circuit model.

34. The method of ANY one of the above method clauses, comprising:

suspending a voltage sensing unit that includes the first sensor from a neutral conductor.

35. The method of ANY one of the above method clauses, comprising:

suspending a voltage sensing unit that includes the first sensor a high-voltage conductor.

36. The method of ANY one of the above method clauses, comprising:

suspending a voltage sensing unit that includes a sensing plate as the first sensor, wherein a shape of the sensing plate is conical.

37. The method of ANY one of the above method clauses, comprising:

suspending a voltage sensing unit that includes a sensing plate as the first sensor, wherein a shape of the sensing plate is spherical.

38. The method of ANY one of the above method clauses, comprising:

suspending a voltage sensing unit that includes a sensing plate as the first sensor, wherein a shape of the sensing plate is semi-spherical.

39. The method of ANY one of the above method clauses, comprising:

suspending a voltage sensing unit that includes a sensing plate as the first sensor, wherein a shape of the sensing plate is semi-spherical.

40. The method of ANY one of the above method clauses, comprising:

configuring a voltage sensing unit that includes the first sensor for high-voltage measurements using an additional secondary capacitive divider.

41. The method of ANY one of the above method clauses, wherein voltage measurements of three sensors are compared to measure voltage at each phase and current is measured at each phase and thereafter a power factor is calculated for each phase.

42. A system for characterizing a power line within an electrical grid including characterizing an unknown line voltage at a first point X1 on the power line, the system comprising:

transistor-based circuitry configured to collect raw voltage at or about the first point X1 using a first sensor;

transistor-based circuitry configured to gather additional data from one or more data collection sources upstream to or downstream to first point X1;

transistor-based circuitry configured to use raw voltage, and environment and line data to calculate a first voltage range at the first point X1; and

transistor-based circuitry configured to use constraining data sequentially to bind the first voltage range from a determined range of possibilities to a single voltage measurement.

43. The system of ANY one of the above system clauses, wherein there is a substation with voltage measuring capacity but no downstream voltage measuring means on the power line local to the first point X1.

44. The system of ANY one of the above system clauses, wherein there is a substation with voltage measuring capacity but no downstream (end of feeder) voltage measuring means (e.g. one or more smart meters) and wherein computing of voltage is achieved by a method comprising:

i) collecting raw voltage data in a voltage sensing unit on the power line at Point X1 (such as, for example, a simple voltage gathering sensor, and which need not necessarily be a fully computational voltage sensing unit);

ii) transmitting raw voltage data to a server on a computing system remote from the sensor (such as for example, in a Cloud), the computing system comprising a microprocessor; and

iii) gathering additional data from substation to Point X1 (constraining data); iv) using raw voltage, and environment and line data (comprising at least one of GPS location of sensor, GIS data of the electrical grid, phase, type of conductor, total load on conductor), to calculate voltage range at Point X1; and v) using constraining data sequentially to bind (narrow and tighten) the voltage range from a determined range of possibilities to a likely true absolute voltage measurement at Point X1.

45. The system of ANY one of the above system clauses, wherein (in respective variants) the system is configured to perform ANY one of the above method clauses.

With respect to the numbered claims expressed below, those skilled in the art will appreciate that recited operations therein may generally be performed in any order. Also, although various operational flows are presented in sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

What is claimed is:

1. A computer-implemented method for characterizing a power line within an electrical grid including characterizing an unknown line voltage at a first point X1 on said power line, said method comprising:
collecting raw voltage in a voltage sensing unit at said first point X1 using a first sensor, wherein said voltage sensing unit comprises said first sensor and wherein there is a substation with voltage measuring capacity but no downstream voltage measuring means on said power line;
transmitting said raw voltage data to a server on a computing system remote from said first sensor, said computing system comprising a microprocessor;
gathering additional data from one or more data collection sources upstream to or downstream to said first point X1, said additional data having been gathered from said substation to said first point X1;
using raw voltage, and environment and line data to calculate a first voltage range at said first point X1; and
using constraining data sequentially to bind said first voltage range from a determined range of possibilities to a single voltage measurement.

2. The method of claim 1, comprising:
configuring a voltage sensing unit by mounting first and second loads thereof in parallel, wherein each of said loads comprises one or more capacitors or one or more resistors and wherein each of said loads is controlled by a corresponding switch; and
accounting for a stray capacitance (Cg) between a neutral conductor and said first sensor by measuring a set of voltages corresponding to differing positions of said switches and fitting measurements so determined to a non-linear circuit model.

3. The method of claim 1, comprising:
obtaining an indication of a voltage source upstream from said first point X1, wherein said voltage source upstream from said first point X1; and
obtaining an acceptable technical line loss of a portion of said power line between said first point X1 and said voltage source upstream from said first point X1 partly based on said indication of said voltage source upstream from said first point X1 and partly based on a phase component of said raw voltage.

4. The method of claim 1, comprising:
obtaining an indication of a voltage source downstream from said first point X1, wherein said voltage source downstream from said first point X1, wherein said voltage source comprises a usage meter; and
obtaining an acceptable technical line loss of a portion of said power line between said first point X1 and said voltage source downstream from said first point X1 partly based on said indication of said voltage source downstream from said first point X1 and partly based on a phase component of said raw voltage.

5. A method for characterizing a power line within an electrical grid including characterizing an unknown line voltage at a first point X1 on said power line, said method comprising:
collecting raw voltage at or about said first point X1 using a first sensor;
gathering additional data from one or more data collection sources upstream to or downstream to said first point X1;
using raw voltage, and environment and line data to calculate a first voltage range at said first point X1; and
using constraining data sequentially to bind said first voltage range from a determined range of possibilities to a single voltage measurement.

6. The method of claim 5, wherein said using said raw voltage, and said environment and line data comprises:
transmitting said raw voltage data to a server on a computing system remote from said sensor, said computing system comprising a microprocessor, and wherein said raw voltage, and environment and line data comprises GPS sensor location.

7. The method of claim 5, wherein said using said raw voltage, and said environment and line data comprises:
transmitting said raw voltage data to a server on a computing system remote from said sensor, said computing system comprising a microprocessor, and wherein said raw voltage, and environment and line data comprises GIS data of said electrical grid.

8. The method of claim 5, wherein said using said raw voltage, and said environment and line data comprises:
transmitting phase and conductor type data to a server on a computing system remote from said sensor, said computing system comprising a microprocessor; and
receiving said first voltage range or said constraining data from said server based on said raw voltage, and said environment and line data.

9. The method of claim 5, wherein said using said raw voltage, and said environment and line data comprises:
transmitting total load on conductor data to a server on a computing system remote from said sensor, said computing system comprising a microprocessor; and
receiving said first voltage range or said constraining data from said server based on said raw voltage, and said environment and line data; and
receiving said first voltage range or said constraining data from said server based on said raw voltage, and said environment and line data.

10. The method of claim 5, wherein said raw voltage is collected in a voltage sensing unit at said first point X1 using a first sensor and wherein said voltage sensing unit comprises said first sensor, said method comprising
transmitting said raw voltage data to a server on a computing system remote from said first sensor, said computing system comprising a microprocessor.

11. The method of claim 5, wherein said unknown line voltage at said first point X1 is sensed using a single contact, said method comprising:
providing a voltage sensing unit, said voltage sensing unit comprising a shielded enclosure hosting a bank of resistors comprising at least two resistors mounted in parallel, each of said at least two resistors being controlled by a corresponding switch, and determining an unknown stray capacitance between a neutral conductor and said voltage sensing unit by measuring a set of voltages corresponding to differing switch positions and fitting measurements so determined to a non-linear circuit model.

12. The method of claim 5, comprising:
suspending a voltage sensing unit that includes said first sensor from a neutral conductor.

13. The method of claim 5, comprising:
suspending a voltage sensing unit that includes said first sensor a high-voltage conductor.

14. The method of claim 5, comprising:
suspending a voltage sensing unit that includes a sensing plate as said first sensor, wherein a shape of said sensing plate is conical.

15. The method of claim 5, comprising:
suspending a voltage sensing unit that includes a sensing plate as said first sensor, wherein a shape of said sensing plate is spherical.

16. The method of claim 5, comprising:
suspending a voltage sensing unit that includes a sensing plate as said first sensor, wherein a shape of said sensing plate is tapered.

17. The method of claim 5, comprising:
suspending a voltage sensing unit that includes a sensing plate as said first sensor, wherein a shape of said sensing plate is semi-spherical.

18. The method of claim 5, comprising:
configuring a voltage sensing unit that includes said first sensor for high-voltage measurements using an additional secondary capacitive divider.

19. The method of claim 5, wherein voltage measurements of three sensors are compared to measure voltage at each phase and current is measured at each phase and thereafter a power factor is calculated for each phase.

20. A method of ascertaining an unknown line voltage at a first point X1 on a power line within an electrical grid, which comprises:
a) collecting raw voltage at or about said first point X1 using a first sensor;
b) gathering additional data from data collection sources upstream or downstream to said first point X1;
c) using raw voltage, and environment and line data to calculate a voltage range at said first point X1; and
d) using constraining data sequentially to bind said voltage range from a determined range of possibilities to a likely absolute voltage measurement.
